(19) United States
(12) Patent Application Publication
(10) Pub. No.: US 2024/0090276 A1
(43) Pub. Date: Mar. 14, 2024

(54) DISPLAY PANEL AND DISPLAY DEVICE

(71) Applicant: LG Display Co., Ltd., Seoil (KR)

(72) Inventors: ChanYong JEONG, Paju-si (KR); Younghyun KO, Paju-si (KR); JuHeyuck BAECK, Seoul (KR)

(73) Assignee: LG Display Co., Ltd., Seoul (KR)

(21) Appl. No.: 18/236,225

(22) Filed: Aug. 21, 2023

(30) Foreign Application Priority Data
Sep. 8, 2022 (KR) 10-2022-0114277

(51) Int. Cl. H10K 59/126; H10K 59/131

(52) U.S. Cl. CPC H10K 59/126; H10K 59/131

(57) ABSTRACT

A display panel include a data signal line for supplying a data signal; a scan signal line for supplying a scan signal; and a subpixel connected to the data signal line and the scan signal line and including a first transistor including a first active layer, a first source electrode connected to one side of the first active layer, a first drain electrode connected to another side of the first active layer, and a first gate electrode overlapping with the first active layer, overlapping with all or at least a portion of the first source electrode, and overlapping with all or at least a portion of the first drain electrode, and are capable of preventing the exposure of the first transistor to light or hydrogen, and thereby preventing a decrease in characteristics of the first transistor due to light or hydrogen.

### CROSS-REFERENCE TO RELATED APPLICATION

This application claims the priority of Korean Patent Application No. 10-2022-0114277, filed on Sep. 8, 2022, which is hereby incorporated by reference in its entirety.

### BACKGROUND

### Field of the Disclosure

The present disclosure relates to electronic devices with a display, and more specifically, to a display panel and a display device.

### Description of the Background

Transistors are widely used as switching devices or driving devices in the field of electronic devices because thin film transistors may be manufactured on a glass substrate or a plastic substrate, the thin film transistors are widely used as a driving element (a driving transistor) or a switching element (or a switching transistor) in display devices such as a liquid crystal display device, an organic light emitting display device, or the like.

However, the transistors may not perform intended desirable functions when they are exposed to light, hydrogen, or the like because characteristics of the transistors such as physical characteristics, electric characteristics, and the like may have changed.

### SUMMARY

To address the above problems, the present disclosure is to provide a display panel and a display device that include transistors having a structure capable of providing desired performance even when being exposed to light, hydrogen, or the like.

More specifically, the present disclosure is to provide a display panel and a display device that include transistors having a structure capable of preventing or reducing the exposure of the transistors to light, hydrogen, or the like even when the transistors have a top-gate structure that is more likely to be exposed to light, hydrogen, or the like.

The present disclosure is also to provide a display panel and a display device that include transistors having a structure capable of preventing or reducing the exposure of the transistors to light, hydrogen, or the like even when the display device has a top-emission structure that is more likely to be exposed to light, hydrogen, or the like.

The present disclosure is also to provide a display panel and a display device that include different types of transistors each designed to have a respective optimized structure according to being advantageous or disadvantageous to a variance in characteristics of the transistors when being exposed to light, hydrogen, or the like.

According to aspects of the present disclosure, a display panel may be provided that includes a data signal line for supplying a data signal, a scan signal line for supplying a scan signal, and a subpixel connected to the data signal line and the scan signal line and including a first transistor.

The first transistor may include a first active layer, a first source electrode connected to one side of the first active layer, a first drain electrode connected to another side of the first active layer, and a first gate electrode overlapping with the first active layer, overlapping with all or at least a portion of the first source electrode, and overlapping with all or at least a portion of the first drain electrode.

The subpixel may further include a light emitting element, a second transistor, and a storage capacitor.

The light emitting element may include a first electrode, an emission layer, and a second electrode.

The second transistor may include a second active layer, a second source electrode connected to one side of the second active layer, a second drain electrode connected to another side of the second active layer, and a second gate electrode overlapping with a portion of the second active layer, but not overlapping with the second source electrode and the second drain electrode.

The first transistor may be a driving transistor, and the second transistor may be a scan transistor, which is a type of switching transistor.

The first gate electrode of the first transistor may be a top-gate electrode located over the first active layer, and the second gate electrode of the second transistor may be a top-gate electrode located over the second active layer.

The first gate electrode has a size greater than that of the second gate electrode, and the first gate electrode is long and wide enough to prevent hydrogen or light penetration into the first active layer.

In the present disclosure, the display panel may further include a side shield disposed between the storage capacitor and the first transistor. For example, the side shield may include a trench-shaped contact hole line (or a trench-shaped contact hole) to which a second capacitor electrode and the first gate electrode are connected.

In one or more aspects, the display panel may further include a substrate, a buffer layer on the substrate, and a lower shield located between the substrate and the buffer layer and overlapping with the first active layer.

For example, the lower shield may be electrically connected to the first source electrode.

In another example, the lower shield may be electrically connected to the first gate electrode.

The first gate electrode may include a first lower gate electrode and a first upper gate electrode. The first lower gate electrode may contact the second capacitor electrode and include a same material as a first capacitor electrode.

In the present disclosure, a light emitting area of the subpixel disposed in the display panel may be located over the storage capacitor.

In the present disclosure, the first gate electrode disposed in the display panel may be formed in a single layer and include a same material as the first capacitor electrode.

In the present disclosure, the light emitting area of the subpixel disposed in the display panel may overlap with the first transistor and be located over the first transistor.

In the present disclosure, in the display panel, an area in which the first source electrode overlap withs the first gate electrode may be greater than an area in which the first drain electrode overlap withs the first gate electrode.

In the present disclosure, in the display panel, an additional storage capacitor may be formed by the overlap with between the first source electrode and the first gate electrode.

According to various aspects of the present disclosure, a display device may be provided that includes a substrate, and first and second transistors on the substrate.

The first transistor may include a first active layer, a first source electrode connected to one side of the first active layer, a first drain electrode connected to another side of the first active layer, and a first gate electrode overlapping with all or at least a portion of the first active layer.

The second transistor may include a second active layer, a second source electrode connected to one side of the second active layer, a second drain electrode connected to another side of the second active layer, and a second gate electrode overlapping with a portion of the second active layer.

The display device may further include a gate insulating layer disposed between the first active layer and the first gate electrode and between the second active layer and the second gate electrode.

For example, a concentration of hydrogen or an amount of light being exposed in a portion between the first active layer and the first gate electrode among portions of the gate insulating layer may be less than a concentration of hydrogen or an amount of light being exposed in a portion between the second active layer and the second gate electrode among the portions of the gate insulating layer.

According to various aspects of the present disclosure, a display panel and a display device may be provided that include transistors having a structure capable of providing desired performance even when being exposed to light, hydrogen, or the like.

According to various aspects of the present disclosure, a display panel and a display device may be provided that include transistors having a structure capable of preventing or reducing the exposure of the transistors to light, hydrogen, or the like even when the transistors have a top-gate structure that is more likely to be exposed to light, hydrogen, or the like.

According to various aspects of the present disclosure, a display panel and a display device may be provided that include transistors having a structure capable of preventing or reducing the exposure of the transistors to light, hydrogen, or the like even when the display device has a top-emission structure that is more likely to be exposed to light, hydrogen, or the like.

According to various aspects of the present disclosure, a display panel and a display device may be provided that include different types of transistors each designed to have a respective optimized structure according to being advantageous or disadvantageous to a variance in characteristics of the transistors when being exposed to light, hydrogen, or the like.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure.

In the drawings:

FIG. 1 illustrates an example schematic system configuration of a display device according to aspects of the present disclosure;

FIGS. 2 and 3 illustrate example equivalent circuits of a subpixel included in the display device according to aspects of the present disclosure;

FIG. 4 illustrates an example system configuration of the display device according to aspects of the present disclosure;

FIG. 5 illustrates an example structure of a display panel according to aspects of the present disclosure;

FIG. 6 is an example cross-sectional view of the display panel according to aspects of the present disclosure;

FIG. 7 is an example plan view of the display panel of FIG. 6;

FIG. 8 is an example plan view illustrating selected portions related to a first transistor in the plan view of FIG. 7;

FIG. 9 is an example plan view illustrating selected portions related to a storage capacitor in the plan view of FIG. 7;

FIG. 10 illustrates distinct characteristics related to blocking light and hydrogen in the display panel according to aspects of the present disclosure;

FIG. 11 illustrates an example parasitic capacitor utilization structure in the display panel according to aspects of the present disclosure;

FIG. 12 is an example cross-sectional view of the display panel according to aspects of the present disclosure;

FIG. 13 is an example cross-sectional view of the display panel according to aspects of the present disclosure;

FIG. 14 is an example plan view of the display panel of FIG. 13;

FIG. 15 is an example plan view illustrating selected portions related to a first transistor in the plan view of FIG. 14;

FIG. 16 is an example plan view illustrating selected portions related to a storage capacitor in the plan view of FIG. 14;

FIG. 17 illustrates example distinct characteristics related to blocking light and hydrogen in the display panel according to the present disclosure;

FIG. 18 illustrates an example parasitic capacitor utilization structure in the display panel according to the present disclosure; and

FIG. 19 is an example cross-sectional view of the display panel according to the present disclosure.

### DETAILED DESCRIPTION

Reference will now be made in detail to aspects of the present disclosure, examples of which may be illustrated in the accompanying drawings. In the following description, the structures, aspects, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example aspects of the present disclosure, are merely given by way of example. Therefore, the present disclosure is not limited to the illustrations in the drawings. Where the terms “comprise,” “have,” “include,” “contain,” “constitute,” and the like are used, one or more other elements may be added unless the term, such as “only,” is used. An element described in the singular form is intended to include a plurality of elements, and vice versa, unless the context clearly indicates otherwise.

Although the terms “first,” “second,” “A”, “B”, “(a)”, or “(b)”, and the like may be used herein to describe various elements, these elements should not be interpreted to be limited by these terms as they are not used to define a particular order or precedence. These terms are used only to distinguish one element from another; thus, related elements should not be interpreted to be limited by these terms as they are not used to define a particular order or precedence. Further, the expression of a first element, a second elements “and/or” a third element should be understood as one of the first, second and third elements or as any or all combinations of the first, second and third elements. By way of example, A, B and/or C may refer to only A, only B, or only C; any or some combination of A, B, and C; or all of A, B, and C.

For the expression that an element or layer is “connected,” “coupled,” or “adhered” to another element or layer, the element or layer may not only be directly connected, coupled, or adhered to another element or layer, but also be indirectly connected, coupled, or adhered to another element or layer with one or more intervening elements or layers “disposed” or “interposed” between the elements or layers, unless otherwise specified. Further, the another element may be included in one or more of the two or more elements connected, combined, or coupled (to) one another.

For the expression that an element or layer “overlap withs,” or the like with another element or layer, the element or layer may not only directly contact, overlap with, or the like with another element or layer, but also indirectly overlap with, or the like with another element or layer with one or more intervening elements or layers “disposed” or “interposed” between the elements or layers, unless otherwise specified.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate (ly),” “direct (ly),” or “close (ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference. In describing a temporal relationship, when the temporal order is described as, for example, “after,” “subsequent,” “next,” or “before,” a case which is not continuous may be included unless a more limiting term, such as “just,” “immediate (ly),” or “direct (ly),” is used. In construing an element, the element is to be construed as including an error or tolerance range even where no explicit description of such an error or tolerance range is provided. Further, the term “may” fully encompasses all the meanings of the term “may.” The term “at least one” should be understood as including any or all combinations of one or more of the associated listed items. For example, the meaning of “at least one of a first element, a second element, and a third element” encompasses the combination of all three listed elements, combinations of any two of the three elements, as well as each individual element, the first element, the second element, and the third element. Hereinafter, various aspects of the present disclosure will be described in detail with reference to the accompanying drawings. In addition, for convenience of description, a scale in which each of elements is illustrated in the accompanying drawings may differ from an actual scale. Thus, the illustrated elements are not limited to the specific scale in which they are illustrated in the drawings.

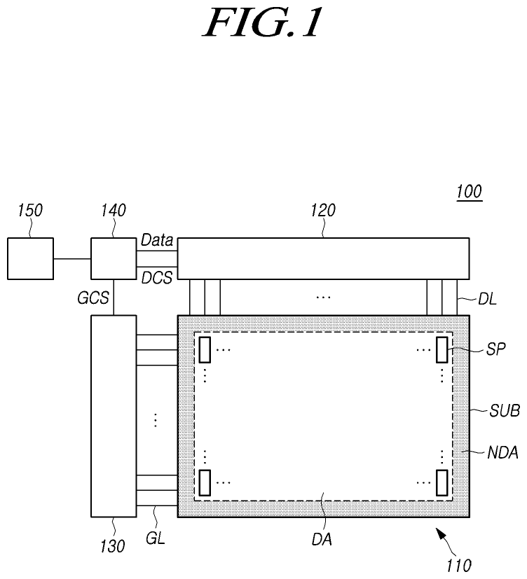

FIG. 1 illustrates an example schematic system configuration of a display device 100 according to aspects of the present disclosure.

Referring to FIG. 1, the display device 100 according to the present disclosure may include a display panel 110 and a driving circuit for driving the display panel 110. The driving circuit may include a data driving circuit 120, a gate driving circuit 130, and the like, and further include a controller 140 for controlling the data driving circuit 120 and the gate driving circuit 130 and a host system 150.

The display panel 110 may include a substrate SUB, and signal lines (also referred to as traces) such as a plurality of data signal lines DL, a plurality of gate signal lines GL, and the like, which are disposed over the substrate SUB. The display panel 110 may further include a plurality of subpixels SP connected to the plurality of gate signal lines GL and the plurality of data signal lines DL.

The display panel 110 may include a display area DA in which an image is displayed and a non-display area NDA in which an image is not displayed. For example, a plurality of subpixels SP for displaying images may be disposed in the display area DA of the display panel 110. The driving circuits including the data driving circuit 120, the gate driving circuit 130 and the controller 140 may be electrically connected to, or may be mounted on, the non-display area NDA of the display panel 110. Further, one or more pads to which one or more integrated circuits or one or more printed circuits are connected, may be disposed in the non-display area NDA.

More specifically, the data driving circuit 120 may be a circuit for driving a plurality of data signal lines DL, and may supply data signals to the plurality of data signal lines DL. The gate driving circuit 130 may be a circuit for driving a plurality of gate signal lines GL, and may supply gate signals to the plurality of gate signal lines GL. The controller 140 may supply a data control signal DCS to the data driving circuit 120 to control an operation time of the data driving circuit 120. The controller 140 may supply a gate control signal GCS to the gate driving circuit 130 to control an operation time of the gate driving circuit 130.

The controller 140 may control scan operation to be initiated according to a respective time set for each frame, convert image data inputted from other devices or other image providing sources (e.g. host system) to a data signal form used in the data driving circuit 120 and then supply image data Data resulting from the converting to the data driving circuit 120, and control the loading of the data to at least one pixel at a predefined time according to a scan process.

The controller 140 may receive, in addition to input image data, several types of timing signals including a vertical synchronous signal (VSYNC), a horizontal synchronous signal (HSYNC), an input data enable signal (DE), a clock signal (CLK), and the like from other devices, networks, or systems (e.g. a host system 150).

To control the data driving circuit 120 and the gate driving circuit 130, the controller 140 may receive one or more of the timing signals such as the vertical synchronization signal (VSYNC), the horizontal synchronization signal (HSYNC), the input data enable signal (DE), the clock signal (CLK), and the like, generate several types of control signals DCS and GCS, and output the generated signals to the data driving circuit 120 and the gate driving circuit 130.

For example, to control the gate driving circuit 130, the controller 140 may output several types of gate control signals GCS including a gate start pulse (GSP), a gate shift clock (GSC), a gate output enable signal (GOE), and the like.

Further, to control the data driving circuit 120, the controller 140 may output several types of data control signals DCS including a source start pulse (SSP), a source sampling clock (SSC), a source output enable (SOE) signal, and the like.

The controller 140 may be implemented as a separate component from the data driving circuit 120, or integrated with the data driving circuit 120 and thus implemented in a single integrated circuit.

The data driving circuit 120 may drive a plurality of data signal lines DL by supplying data voltages corresponding to image data Data received from the controller 140 to the plurality of data signal lines DL. The data driving circuit 120 may also be referred to as a source driving circuit.

The data driving circuit 120 may include, for example, one or more source driver integrated circuits SDIC.

Each source driver integrated circuit SDIC may include a shift register, a latch circuit, a digital-to-analog converter DAC, an output buffer, and the like. In one or more aspects, each source driver integrated circuit SDIC may further include an analog to digital converter ADC.

In one or more aspects, each source driver integrated circuit SDIC may be connected to the display panel 110 in a tape automated bonding (TAB) type, or connected to a conductive pad such as a bonding pad of the display panel 110 in a chip on glass (COG) type or a chip on panel (COP) type, or connected to the display panel 110 in a chip on film (COF) type.

The gate driving circuit 130 may supply a gate signal of a turn-on level voltage or a gate signal of a turn-off level voltage according to the control of the controller 140. The gate driving circuit 130 may sequentially drive a plurality of gate signal lines GL by sequentially supplying the gate signals of the turn-on level voltage to the plurality of gate signal lines GL.

In one or more aspects, the gate driving circuit 130 may be connected to the display panel 110 in the tape automated bonding (TAB) type, or connected to a conductive pad such as a bonding pad of the display panel 110 in the chip on glass (COG) type or the chip on panel (COP) type, or connected to the display panel 110 in the chip on film (COF) type. In one or more aspects, the gate driving circuit 130 may be disposed in the non-display area NDA of the display panel 110 in a gate in panel (GIP) type. The gate driving circuit 130 may be disposed on or over a substrate SUB, or connected to the substrate SUB. That is, in the case of the GIP type, the gate driving circuit 130 may be disposed in the non-display area NDA of the substrate SUB. The gate driving circuit 130 may be connected to the substrate SUB in the case of the chip on glass (COG) type, the chip on film (COF) type, or the like.

For example, at least one of the data driving circuit 120 and the gate driving circuit 130 may be disposed in the display area DA. In this example, at least one of the data driving circuit 120 and the gate driving circuit 130 may be disposed not to overlap with subpixels SP, or disposed to overlap with one or more, or all, of the subpixels SP.

When a specific gate signal line is selected and driven by the gate driving circuit 130, the data driving circuit 120 may convert image data Data received from the controller 140 into data voltages in an analog form and supply the data voltages resulting from the converting to a plurality of data signal lines DL.

The data driving circuit 120 may be located on or electrically connected to, but not limited to, only one side or portion (e.g., an upper edge or a lower edge) of the display panel 110. In one or more aspects, the data driving circuit 120 may be located on or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or the like.

The gate driving circuit 130 may be located in only one side or portion (e.g., a left edge or a right edge) of the display panel 110. In one or more aspects, the gate driving circuit 130 may be connected to two sides or portions (e.g., a left edge and a right edge) of the display panel 110, or be connected to at least two of four sides or portions (e.g., an upper edge, a lower edge, the left edge, and the right edge) of the display panel 110 according to driving schemes, panel design schemes, or the like.

The controller 140 may be a timing controller used in the typical display technology or a control apparatus/device capable of additionally performing other control functionalities in addition to the typical function of the timing controller. In one or more aspects, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like.

The controller 140 may be mounted on a printed circuit board, a flexible printed circuit, or the like, and may be electrically connected to the data driving circuit 120 and the gate driving circuit 130 through the printed circuit board, the flexible printed circuit, or the like.

The controller 140 may transmit signals to, and receive signals from, the data driving circuit 120 via one or more predetermined interfaces. In some aspects, such interfaces may include a low voltage differential signaling (LVDS) interface, an EPI interface, a serial peripheral interface (SPI), and the like.

The controller 140 may include a storage medium such as one or more registers.

In one or more aspects, the display device 100 may be a display including a backlight unit such as a liquid crystal display device, or may be a self-emission display such as an organic light emitting diode (OLED) display, a quantum dot (QD) display, a micro light emitting diode (M-LED) display, and the like.

In an aspect where the display device 100 according to aspects of the present disclosure is implemented using an OLED display, each subpixel SP may include, as a light emitting element, an organic light emitting diode (OLED), which is a self-emission element. In an aspect where the display device 100 according to aspects of the present disclosure is implemented using a QD display, each subpixel SP may include a light emitting element configured with quantum dots, which are self-emission semiconductor crystals. In an aspect where the display device 100 according to aspects of the present disclosure is implemented using a micro LED display, each subpixel SP may include, as a light emitting element, a micro light emitting diode (Micro LED), which is a self-emission element and including an inorganic material.

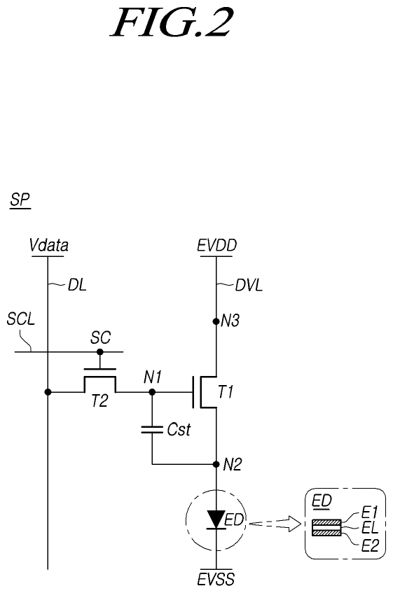

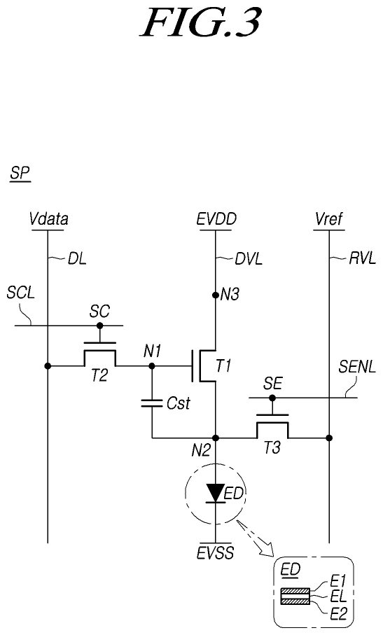

FIGS. 2 and 3 illustrate example equivalent circuits of a subpixel SP included in the display device 100 according to aspects of the present disclosure.

Referring to FIG. 2, each of a plurality of subpixels SP disposed in the display panel 110 of the display device 100 according to aspects of the present disclosure may include a light emitting element ED, a first transistor T1, a second transistor T2, and a storage capacitor Cst.

Referring to FIG. 2, the light emitting element ED may include a first electrode E1, a second electrode E2, and an emission layer EL located between the first electrode E1 and the second electrode E2.

For example, the first electrode E1 of the light emitting element ED may be a pixel electrode disposed in each subpixel SP, and the second electrode E2 may be a common electrode commonly disposed in all or at least some of the plurality of subpixels SP. In another example, the first electrode E1 may be a common electrode, and the second electrode E2 may be a pixel electrode. A base voltage EVSS, which is a type of common voltage for display driving, may be applied to the second electrode E2 or the first electrode E1 serving as the common electrode.

For example, the first electrode E1 may be an anode electrode, and the second electrode E2 may be a cathode electrode. In another example, the first electrode E1 may be a cathode electrode and the second electrode E2 may be an anode electrode.

Hereinafter, for convenience, descriptions are provided based on examples where the first electrode E1 is a pixel electrode and an anode electrode, and the second electrode E2 is a common electrode and a cathode electrode. It should be noted that the scope of the present disclosure includes examples where the first electrode E1 is a common electrode and a cathode electrode, and the second electrode E2 is a pixel electrode and an anode electrode.

In one or more aspects, the light emitting element ED may be an organic light emitting diode (OLED), a light emitting diode (LED), a quantum dot light emitting element or the like.

The first transistor T1 may be a driving transistor for driving the light emitting element ED, and may include, for example, a first node N1, a second node N2, and a third node N3.

The first node N1 of the first transistor T1 may be a gate node of the first transistor T1, and be electrically connected to a source node or a drain node of the second transistor T2.

The second node N2 of the first transistor T1 may be a source node or a drain node of the first transistor T1, be electrically connected to a source node or a drain node of a third transistor T3, and further be electrically connected to the first electrode E1 of the light emitting element ED.

The third node N3 of the first transistor T1 may be electrically connected to a driving voltage line DVL for supplying a driving voltage EVDD, which is another type of common voltage for display driving.

The second transistor T2 may be turned on or off by a scan signal SC, which is a type of gate signal, and may be connected between the first node N1 of the first transistor T1 and a data signal line DL. The second transistor T2 is also referred to as a scan transistor.

The second transistor T2 may be turned on or off according to the scan signal SC supplied through a scan signal line SCL, and control an electrical connection between the data signal line DL and the first node N1 of the first transistor T1. The scan signal line SCL may be one type of gate signal line GL, and the scan signal SC may be one type of gate signal.

The second transistor T2 may be turned on by the scan signal SC having a turn-on level voltage, and transmit a data signal Vdata supplied through the data signal line DL to the first node N1 of the first transistor T1.

In an example where the second transistor T2 is an n-type transistor, the turn-on level voltage of the scan signal SC may be a high level voltage. In another example where the second transistor T2 is a p-type transistor, the turn-on level voltage of the scan signal SC may be a low level voltage.

The storage capacitor Cst may be connected between the first node N1 and the second node N2 of the first transistor T1.

The storage capacitor Cst may store the amount of electric charge corresponding to a voltage difference between both terminals and maintain the voltage difference between both terminals for a predetermined frame time. Accordingly, a corresponding subpixel SP may emit light for the predetermined frame time.

Referring to FIG. 3, each of a plurality of subpixels SP disposed in the display panel 110 of the display device 100 according to the present disclosure may further include a third transistor T3.

The third transistor T3 may be controlled by a sensing signal SE, which is a type of gate signal, and may be connected between the second node N2 of the first transistor T1 and a reference voltage line RVL. The third transistor T3 is also referred to as a sensing transistor.

In other words, the third transistor T3 may be turned on or off according to the sensing signal SE supplied through a sensing signal line SENL, which is another type of the gate signal line GL, and control an electrical connection between the reference voltage line RVL and the second node N2 of the first transistor T1.

The third transistor T3 may be turned on by the sensing signal SE having a turn-on level voltage, and transmit a reference voltage Vref supplied from the reference voltage line RVL to the second node N2 of the first transistor T1.

The third transistor T3 may be turned on by the sensing signal SE having the turn-on level voltage and transmit a voltage of the second node N2 of the first transistor T1 to the reference voltage line RVL.

In an example where the third transistor T3 is an n-type transistor, the turn-on level voltage of the sensing signal SE may be a high level voltage. In another example where the third transistor T3 is a p-type transistor, the turn-on level voltage of the sensing signal SE may be a low level voltage.

The function of the third transistor T3 transmitting the voltage of the second node N2 of the first transistor T1 to the reference voltage line RVL may be used in a sensing mode for sensing at least one characteristic value of a corresponding subpixel SP. In this case, the voltage transmitted to the reference voltage line RVL may be a voltage for calculating at least one characteristic value of the subpixel SP or a voltage to which the at least one characteristic value of the subpixel SP is added or counted.

Herein, the at least one characteristic value of the subpixel SP may be a characteristic value of the first transistor T1 or the light emitting element ED. The characteristic value of the first transistor T1 may include a threshold voltage, mobility, and the like of the first transistor T1. The characteristic value of the light emitting element ED may include a threshold voltage of the light emitting element ED.

In the display panel 110 according to various aspects of the present disclosure, the first transistor T1, the second transistor T2, and the third transistor T3 may be n-type transistors or p-type transistors. Herein, for convenience of explanation, the first transistor T1, the second transistor T2, and the third transistor T3 are considered to be n-type transistors.

In the display panel 110 according to various aspects of the present disclosure, the first transistor T1 is referred to as a driving transistor for controlling the flow of current (which may referred to as current driving), and the second transistor T2 and the third transistor T3 are referred to as switching transistors for performing a switching function.

The storage capacitor Cst may be an external capacitor intentionally designed to be located outside of the first transistor T1, other than an internal capacitor, such as a parasitic capacitor (e.g., Cgs or Cgd), that may be formed between the gate node and the source node (or drain node) of the first transistor T1.

In one aspect, the scan signal line SCL and the sensing signal line SENL may be different gate signal lines GL from each other. In this aspect, the scan signal SC and the sensing signal SE may be separate gate signals, and respective turn-on and turn-off times of the second transistor T2 and the third transistor T3 included in one subpixel SP may be independent of each other. That is, the respective turn-on and turn-off times of the second transistor T2 and the third transistor T3 included in one subpixel SP may be equal to, or different from, each other.

In another aspect, the scan signal line SCL and the sensing signal line SENL may be a same gate signal line GL. That is, the gate node of the second transistor T2 and the gate node of the third transistor T3 included in one subpixel SP may be connected to one gate signal line GL. In this aspect, the scan signal SC and the sensing signal SE may be the same gate signal, and respective turn-on and turn-off times of the second transistor T2 and the third transistor T3 included in one subpixel SP may be the same.

The structures of the subpixel SP shown in FIGS. 2 and 3 are merely examples, and may be variously modified by further including one or more transistors or one or more capacitors.

Further, although discussions on the subpixel structures of FIGS. 2 and 3 have been provided based on an example where the display device 100 is a self-emission display device, in an example where the display device 100 is a liquid crystal display, each subpixel SP may include a transistor, a pixel electrode, and the like.

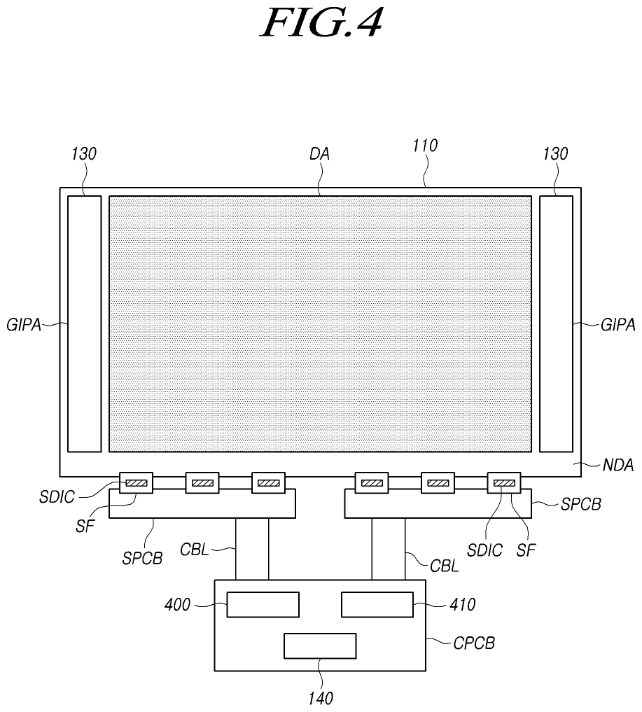

FIG. 4 illustrates an example system configuration of the display device 100 according to various aspects of the present disclosure.

Referring to FIG. 4, the display panel 110 may include a display area DA in which an image is displayed and a non-display area NDA in which an image is not displayed.

Referring to FIG. 4, when the data driving circuit 120 includes one or more source driver integrated circuits SDIC and is implemented as the chip on film (COF) type, each source driver integrated circuit SDIC may be mounted on a circuit film SF connected to the non-display area NDA of the display panel 110.

Referring to FIG. 4, the gate driving circuit 130 may be implemented as the gate in panel (GIP) type. In this aspect, the gate driving circuit 130 may be disposed in a gate driving circuit area GIPA included in the non-display area NDA of the display panel 110. In another aspect, unlike the illustration in FIG. 4, the gate driving circuit 130 may be implemented as the chip on film (COF) type.

For a circuital connection between one or more source driver integrated circuits SDIC and other devices, components, and the like, the display device 100 may include at least one source printed circuit board SPCB, and a control printed circuit board CPCB on which control components, and various types of electrical devices or components are mounted.

The circuit film SF on which the source driver integrated circuit SDIC is mounted may be connected to at least one source printed circuit board SPCB. That is, one side of the circuit film SF on which the source driver integrated circuit SDIC is mounted may be electrically connected to the display panel 110, and another side thereof may be electrically connected to the source printed circuit board SPCB.

The controller 140, a power management integrated circuit (PMIC) 410, and the like may be mounted on the control printed circuit board CPCB. The controller 140 may perform an overall control function related to the driving of the display panel 110 and control operations of the data driving circuit 120 and the gate driving circuit 130. The power management integrated circuit 410 may supply various types of voltages or currents to the data driving circuit 120 and the gate driving circuit 130, or control various types of voltages or currents to be supplied.

A circuital connection between at least one source printed circuit board SPCB and the control printed circuit board CPCB may be performed through at least one connection cable CBL. The connection cable CBL may be, for example, a flexible printed circuit FPC, a flexible flat cable FFC, or the like.

At least one source printed circuit board SPCB and the control printed circuit board CPCB may be integrated into, and implemented in, one printed circuit board.

In one or more aspects, the display device 100 according to aspects of the present disclosure may further include a level shifter 400 for adjusting a voltage level. For example, the level shifter 400 may be disposed on the control printed circuit board CPCB or the source printed circuit board SPCB.

In particular, in the display device 100 according to aspects of the present disclosure, the level shifter 400 may supply signals needed for gate driving to the gate driving circuit 130. For example, the level shifter 400 may supply a plurality of clock signals to the gate driving circuit 130. Then, the gate driving circuit 130 may generate a plurality of gate signals (e. g., scan signals SC, sensing signals SE, and/or the like) based on a plurality of clock signals input from the level shifter 400, and output the generated signals to a plurality of gate signal lines GL (e. g., scan signal lines SCL, and/or sensing signal line SENL). The plurality of gate signal lines GL may deliver a plurality of gate signals (e. g., scan signals SC, sensing signals SE, and/or the like) to subpixels SP disposed in the display area DA of the substrate SUB.

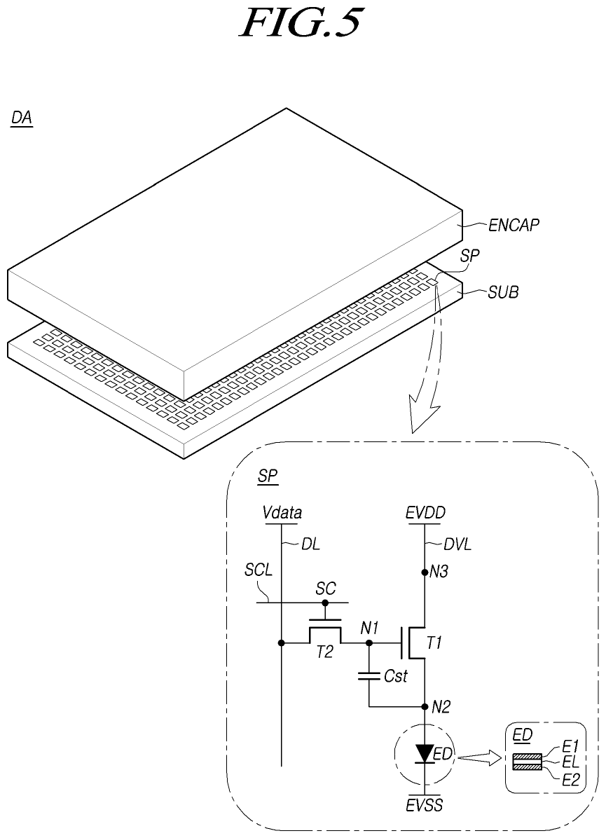

FIG. 5 illustrates an example structure of the display panel 100 according to various aspects of the present disclosure.

Referring to FIG. 5, each of subpixels SP disposed in the display area DA of the display panel 110 may include a light emitting element ED, a first transistor T1 for driving the light emitting element ED, a second transistor T2 for transmitting a data signal Vdata to a first node N1 of the first transistor T1, and a storage capacitor Cst for maintaining a voltage at an approximate constant level during one frame.

The first transistor T1 may include the first node N1 to which a data signal Vdata is applied, a second node N2 electrically connected to the light emitting element ED, and a third node N3 to which a driving voltage EVDD through a driving voltage line DVL is applied. In first transistor T1, the first node N1 may be a gate node, the second node N2 may be a source node or a drain node, and the third node N3 may be the drain node or the source node. Hereinafter, for convenience of description, descriptions will be provided based on examples where the first node N1 of the first transistor T1 is the gate node, the second node N2 of the first transistor T1 is the source node or the drain node, and the third node N3 of the first transistor T1 is the drain node or the source node.

The light emitting element ED may include a first electrode E1, an emission layer EL, and a second electrode E2. The first electrode E1 of the light emitting element ED may be electrically connected to the second node N2 of the first transistor T1 of each subpixel SP. The second electrode E2 of the light emitting element ED may receive a base voltage EVSS.

The light emitting element ED may be, for example, an organic light emitting diode (OLED), an inorganic light emitting diode, a quantum dot light emitting element, or the like. In an aspect where an organic light emitting diode (OLED) is used as the light emitting element ED, the emission layer EL thereof may include an organic emission layer including an organic material.

The second transistor T2 may be turned on or off by a scan signal SC, which is a type of gate signal delivered through a scan signal line SCL, and may be connected between the first node N1 of the first transistor T1 and a data signal line DL.

The storage capacitor Cst may be connected between the first node N1 and the second node N2 of the first transistor T1.

Referring to FIG. 5, each of the plurality of subpixels SP disposed in the display area DA of the display panel 110 of the display device 100 may basically include a light emitting element ED, two transistors such as a driving transistor and a switching transistor, and one capacitor Cst.

Each of the plurality of subpixels SP disposed in the display area DA of the display panel 110 of the display device 100 may further include one or more transistors or one or more capacitors.

Referring to FIG. 5, since circuit elements (in particular, a light emitting element ED) in each subpixel SP are vulnerable to external moisture or oxygen, an encapsulation layer ENCAP may be disposed in the display panel 110 to prevent the external moisture or oxygen from penetrating into the circuit elements (in particular, the light emitting element ED).

The encapsulation layer ENCAP may be disposed to have various types or shapes.

In one aspect, the encapsulation layer ENCAP may be disposed such that it covers the light emitting elements ED. The encapsulation layer ENCAP may include one or more inorganic layers and one or more organic layers.

In another aspect, the encapsulation layer ENCAP may include an encapsulation substrate, one or more dams located between a thin film transistor array substrate and the encapsulation substrate along an outer edge of the display area DA, and a filler filled in an inner space of the one or more dam.

In one or more aspects, the display panel 110 may have a top-emission structure in which light is emitted in a direction toward the encapsulation layer ENCAP from the substrate SUB, or a bottom-emission structure in which light is emitted in a direction toward the substrate SUB from the encapsulation layer ENCAP. Hereinafter, for convenience of description, discussions will be provided based on examples where the display panel 110 according to aspects of the present disclosure has the top-emission structure.

In one or more aspects, each subpixel SP disposed in the display panel 110 may be connected to a data signal line DL for delivering a data signal Vdata and a scan signal line SCL for delivering a scan signal SC, and include a light emitting element ED, a first transistor T1, a second transistor T2, and a storage capacitor Cst. For example, the light emitting element ED may include a first electrode E1, an emission layer EL, and a second electrode E2.

In the process of manufacturing the display panel 110, when the first transistor T1 serving as a driving transistor in each subpixel SP is exposed to hydrogen or light, the threshold voltage of the first transistor T1 may be decreased. A corresponding subpixel SP including the first transistor T1 having a reduced threshold voltage may operate abnormally. Such a driving defect may lead image quality to become poor.

In a situation where a first transistor T1 has a structure in which a gate insulating layer is etched or has a top-gate structure, the first transistor T1 may be easily exposed to hydrogen or light.

In addition, when the first transistor T1 is an oxide semiconductor transistor, a phenomenon in which the threshold voltage of the first transistor T1 changes by hydrogen or light may easily occur.

To manufacture the display panel 110 capable of preventing the first transistor T1 from being exposed to hydrogen or light, a complicated process and many masks are needed, this leading the manufacturing of the display panel 110 to be problematic.

In some instances, hydrogen or light may be generated during the process of manufacturing the display panel 110 or may be remained or generated inside of the display panel even after the manufacturing of the display panel 110 is completed. For example, hydrogen may be generated in various layers (in particular, various types of insulating layers) located over the first transistor T1, and travel toward the first transistor T1. Light emitted from the light emitting element ED located over the first transistor T1 may travel toward the first transistor T1. In addition, external light may be incident from the first transistor T1 above, and travel toward the first transistor T1.

To address these issues, in one or more aspects, the display panel 110 may be provided that has a structure in which first transistors T1 are not exposed to hydrogen or light (hereinafter, which may be referred to as a hydrogen and/or light blocking structure). Further, in one or more aspects, the display panel 110 may have a structure capable of being manufactured using a small number of masks.

Hereinafter, in the display panel 110 according to aspects of the present disclosure, an example first transistor T1 having a hydrogen and/or light blocking structure will be described.

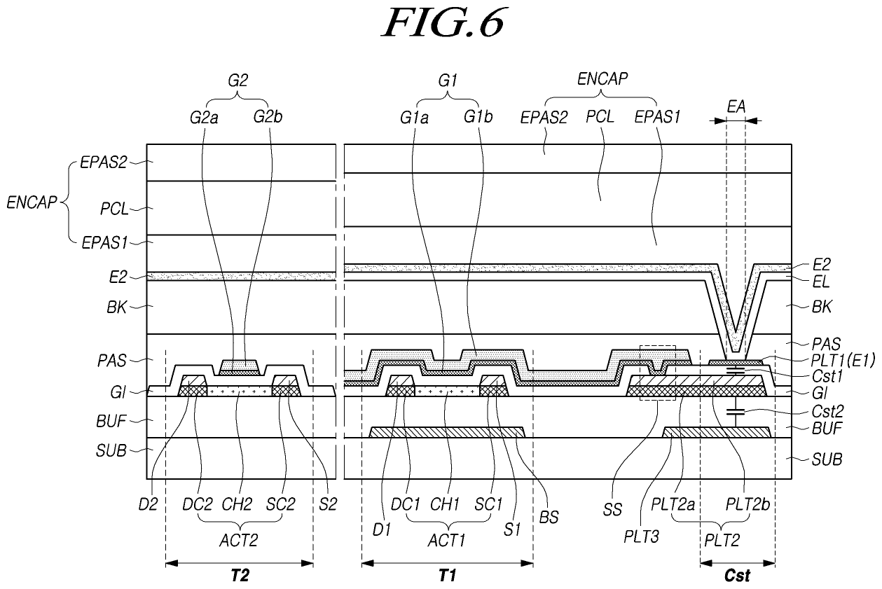

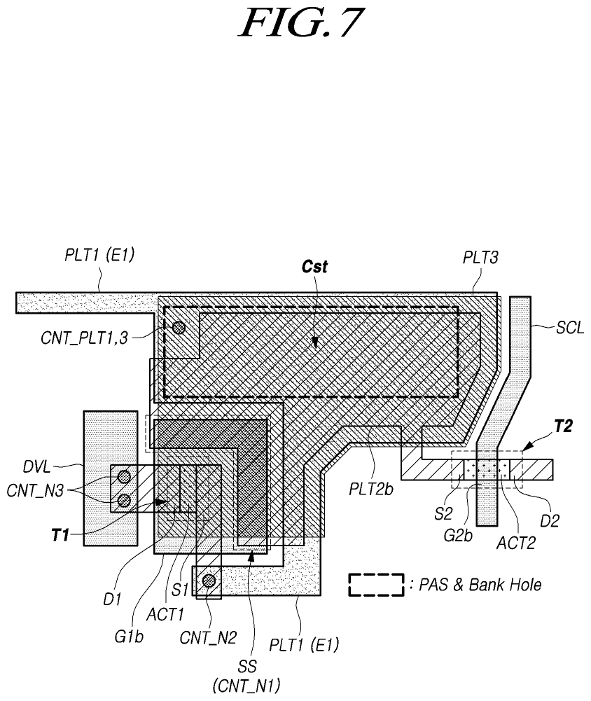

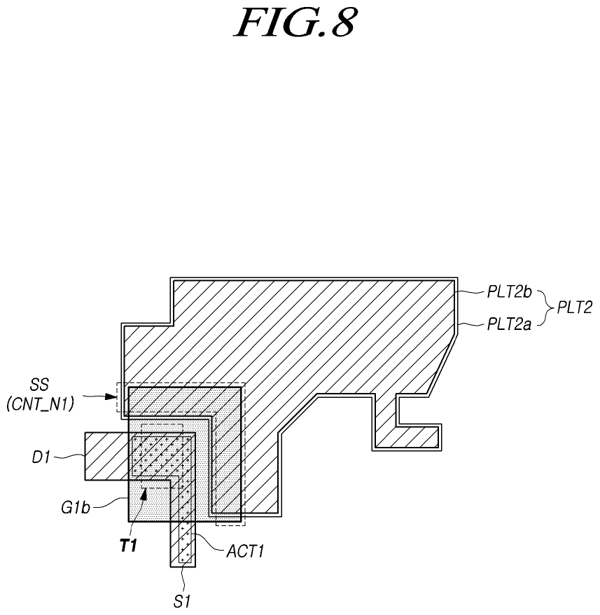

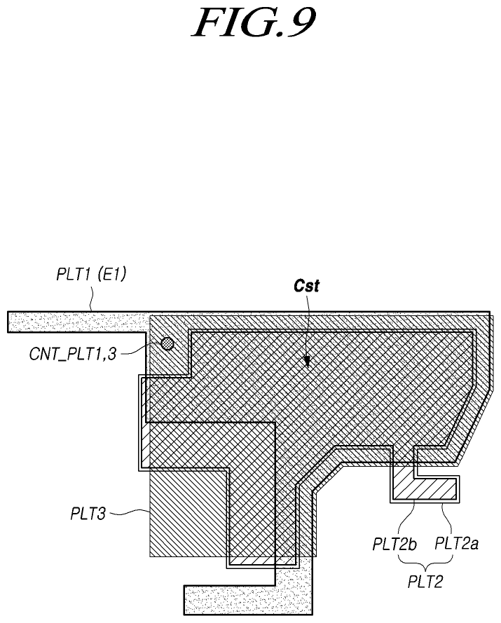

FIG. 6 is an example cross-sectional view of the display panel 110 according to aspects of the present disclosure. FIG. 7 is an example plan view of the display panel of FIG. 6. FIG. 8 is an example plan view illustrating selected portions related to the first transistor T1 in the plan view of FIG. 7. FIG. 9 is an example plan view illustrating selected portions related to a storage capacitor in the plan view of FIG. 7.

Referring to FIG. 6, in one or more aspects, in the display panel 110 according to aspects of the present disclosure, a light emitting element ED, a first transistor T1, a second transistor T2, and a storage capacitor Cst may be disposed in an area where one subpixel SP is formed.

To implement this configuration, in one or more aspects, the display panel 110 may include a substrate SUB and a buffer layer BUF on the substrate SUB.

In one or more aspects, in the display panel 110, the first transistor T1, the second transistor T2, and the storage capacitor Cst may be disposed on the buffer layer BUF.

In one or more aspects, the display panel 110 may include a gate insulating layer GI to form the first transistor T1, the second transistor T2, and the storage capacitor Cst.

In one or more aspects, the display panel 110 may further include a protective layer PAS disposed on the first transistor T1, the second transistor T2, and the storage capacitor Cst. The protective layer PAS may be a layer for protecting the first transistor T1, the second transistor T2, and the storage capacitor Cst.

In one or more aspects, the display panel 110 may further include a gate insulating layer GI for insulating between first and second gate electrodes (G1 and G2) and first and second active layers (ACT1 and ACTT2) of the first and second transistors (T1 and T2).

In one or more aspects, the display panel 110 may further include a bank BK disposed on the protective layer PAS. The bank BK may be a layer for defining a subpixel SP and may be a layer for defining a light emitting area EA of the subpixel SP.

For example, the protective layer PAS may include various insulating layer materials such as silicon nitride (SiNx), silicon oxide (SiOX), or the like. In particular, the protective layer PAS may include silicon nitride (SiNx).

For example, the gate insulating layer GI may include various insulating materials such as silicon oxide (SiOX), silicon nitride (SiNx), or the like.

For example, the buffer layer BUF may include various insulating materials such as silicon oxide (SiOX), silicon nitride (SiNx), or the like.

In one or more aspects, the display panel 110 may further include an encapsulation layer ENCAP for preventing penetration of moisture or oxygen into the light emitting element ED.

The encapsulation layer ENCAP may include a first encapsulation layer EPAS1, a second encapsulation layer PCL, and a third encapsulation layer EPAS2. The first encapsulation layer EPAS1 may be located on a second electrode E2 of the light emitting element ED, the second encapsulation layer PCL may be located on the first encapsulation layer EPAS1, and the third encapsulation layer EPAS2 may be located on the second encapsulation layer PCL. The first encapsulation layer EPAS1 and the third encapsulation layer EPAS2 may be, for example, an inorganic material layer, and the second encapsulation layer PCL may be, for example, an organic material layer.

Referring to FIGS. 6 to 9, the first transistor T1 may include a first active layer ACT1, a first source electrode S1, a first drain electrode D1, and a first gate electrode G1.

The first source electrode S1 may be connected to one side of the first active layer ACT1.

The first drain electrode D1 may be connected to another side of the first active layer ACT1.

The first gate electrode G1 may overlap with the first active layer ACT1, overlap with all or at least a portion of the first source electrode S1, and overlap with all or at least a portion of the first drain electrode D1.

The first active layer ACT1 may include a first channel region CH1, a first source connection region SC1 located on one side of the first channel region CH1, and a first drain connection region DC1 located on another side of the first channel region CH1.

For example, the first source electrode S1 and the first drain electrode D1 may include copper, aluminum, molybdenum (Mo), titanium (Ti), molybdenum-titanium (MoTi), or the like. For example, the first source electrode S1 and the first drain electrode D1 may include a transparent conductive oxide. For example, the transparent conductive oxide (TCO) may include one or more of indium zinc oxide (IZO), indium tin oxide (ITO), indium-gallium-zinc oxide (IGZO), Indium gallium zinc tin oxide (IGZTO), zinc oxide (ZnO), aluminum-doped zinc oxide (AZO), gallium-doped zinc oxide (GZO), antimony tin oxide (ATO), fluorine-doped transparent oxide (FTO), and the like.

For example, the first gate electrode G1 may include copper, aluminum, molybdenum (Mo), titanium (Ti), molybdenum-titanium (MoTi), or the like. For example, the first gate electrode G1 may include a transparent conductive oxide.

For example, the first active layer ACT1 may include an oxide semiconductor material. The oxide semiconductor material may be a semiconductor material obtained by controlling conductivity and adjusting a bandgap through doping of an oxide material, and may generally be a transparent semiconductor material having a wide bandgap. For example, such an oxide semiconductor material may include indium gallium zinc oxide (IGZO), indium gallium zinc tin oxide (IGZTO), zinc oxide (ZnO), cadmium oxide (CdO), indium oxide (InO), zinc tin oxide (ZTO), zinc indium tin oxide (ZITO), and/or the like. In an example where the active layer ACT includes an oxide semiconductor material, such a transistor is referred to as an oxide thin film transistor. The first active layer ACT1 may be formed in a single layer or a multilayer. In an example where the first active layer ACT1 is formed in a multilayer, the first active layer ACT1 may include a multilayer formed with a same semiconductor material or a multilayer formed with two or more different semiconductor materials.

The first source electrode S1 may be disposed on the first source connection region SC1 of the first active layer ACT1. The first drain electrode D1 may be disposed on the first drain connection region DC1 of the first active layer ACT1.

Referring to FIGS. 6 to 9, the second transistor T2 may include a second active layer ACT2, a second source electrode S2, a second drain electrode D2, and a second gate electrode G2.

The second source electrode S2 may be connected to one side of the second active layer ACT2.

The second drain electrode D2 may be connected to another side of the second active layer ACT2.

The second gate electrode G2 may overlap with a portion of the second active layer ACT2, and may not overlap with the second source electrode S2 and the second drain electrode D2.

For example, the second source electrode S2 and the second drain electrode D2 may include copper, aluminum, molybdenum (Mo), titanium (Ti), molybdenum-titanium (MoTi), or the like. For example, the second source electrode S2 and the second drain electrode D2 may include a transparent conductive oxide. For example, the transparent conductive oxide (TCO) may include one or more of indium zinc oxide (IZO), indium tin oxide (ITO), indium-gallium-zinc oxide (IGZO), Indium gallium zinc tin oxide (IGZTO), zinc oxide (ZnO), aluminum-doped zinc oxide (AZO), gallium-doped zinc oxide (GZO), antimony tin oxide (ATO), fluorine-doped transparent oxide (FTO), and the like.

For example, the second gate electrode G2 may include copper, aluminum, molybdenum (Mo), titanium (Ti), molybdenum-titanium (MoTi), or the like. For example, the second gate electrode G2 may include a transparent conductive oxide.

For example, the second active layer ACT2 may include an oxide semiconductor material. The oxide semiconductor material may be a semiconductor material obtained by controlling conductivity and adjusting a bandgap through doping of an oxide material, and may generally be a transparent semiconductor material having a wide bandgap. For example, such an oxide semiconductor material may include indium gallium zinc oxide (IGZO), indium gallium zinc tin oxide (IGZTO), zinc oxide (ZnO), cadmium oxide (CdO), indium oxide (InO), zinc tin oxide (ZTO), zinc indium tin oxide (ZITO), and/or the like. In an example where the active layer ACT includes an oxide semiconductor material, such a transistor is referred to as an oxide thin film transistor. The second active layer ACT2 may be formed in a single layer or a multilayer. In an example where the second active layer ACT2 is formed in a multilayer, the second active layer ACT2 may include a multilayer formed with a same semiconductor material or a multilayer formed with two or more different semiconductor materials.

Referring to FIGS. 6 to 9, as described above, the first gate electrode G1 of the first transistor T1 may overlap with the first active layer ACT1, and further overlap with the first source electrode S1 and the first drain electrode D1.

Thereby, the first gate electrode G1 can block hydrogen or light from entering the first active layer ACT1 of the first transistor T1 from the protective layer PAS. Accordingly, a phenomenon in which the threshold voltage of the first transistor T1 decreases (hereinafter, which may be referred to as a negative shift in the threshold voltage) can be prevented. As a result, the driving performance of the first transistor T1, which is required to serve as a driving transistor, may be improved.

Referring to FIGS. 6 to 9, as described above, while the first gate electrode G1 of the first transistor T1 may overlap with the first active layer ACT1, and further overlap with the first source electrode S1 and the first drain electrode D1, the second gate electrode G2 of the second transistor T2 may overlap with a portion of the second active layer ACT2, but not overlap with the second source electrode S2 and the second drain electrode D2.

Thereby, hydrogen or light may enter the second active layer ACT2 of the second transistor T2 from the protective layer PAS. This may cause a phenomenon in which the threshold voltage of the second transistor T2 decreases (i.e., a negative shift in the threshold voltage). As a result, the switching performance and reliability of the second transistor T2, which are required to serve as a switching transistor, may be improved.

The first gate electrode G1 may have a size greater than that of the second gate electrode G2, and the first gate electrode G1 is long and wide enough to prevent hydrogen or light penetration into the first active layer ACT1. On the other hand, the second gate electrode G2 does not completely cover the second active layer ACT2, thus allowing hydrogen or light penetration into the second active layer ACT2.

Connection relationships between the light emitting element ED, the first transistor T1, the second transistor T2, and the storage capacitor Cst will be briefly described below with reference to FIGS. 6 to 9.

The first gate electrode G1 of the first transistor T1 may be the second source electrode S2 of the second transistor T2 or be electrically connected to the second source electrode S2 of the second transistor T2.

The first source electrode S1 of the first transistor T1 may be the first electrode E1 of the light emitting element ED or be electrically connected to the first electrode E1 of the light emitting element ED.

The first drain electrode D1 of the first transistor T1 may be electrically connected to a driving voltage line DVL (e.g., the driving voltage line DVL in FIG. 5).

The second gate electrode G2 of the second transistor T2 may be a portion of a scan signal line SCL (e.g., the scan signal line SCL in FIG. 5) or be electrically connected to the scan signal line SCL.

The second drain electrode D2 of the second transistor T2 may be a portion of a data signal line DL (e.g., the data signal line DL in FIG. 5) or be electrically connected to the data signal line DL.

The second source electrode S2 of the second transistor T2 may be the first gate electrode G1 of the first transistor T1 or be electrically connected to the first gate electrode G1.

The storage capacitor Cst may include a first capacitor electrode PLT1 and a second capacitor electrode PLT2.

The first capacitor electrode PLT1 may be the first source electrode S1 of the first transistor T1 or be electrically connected to the first source electrode S1 of the first transistor T1.

The second capacitor electrode PLT2 may be the first gate electrode G1 of the first transistor T1 or be electrically connected to the first gate electrode G1 of the first transistor T1.

The second capacitor electrode PLT2 may include a second lower capacitor electrode PLT2a and a second upper capacitor electrode PLT2b.

The second lower capacitor electrode PLT2a may include a same material as the first and second source electrodes S1 and S2 and the first and second drain electrodes D1 and D2. That is, the second lower capacitor electrode PLT2a may be disposed in the same material layer as the first and second source electrodes S1 and S2 and the first and second drain electrodes D1 and D2.

The second upper capacitor electrode PLT2b may include a same semiconductor material as the first and second active layers ACT1 and ACT2. For example, the semiconductor material included in the second upper capacitor electrode PLT2b may be in a conductivity-enabled state or may be in a non-conductivity-enabled state. That is, the second upper capacitor electrode PLT2b may be disposed in the same material layer as the first and second active layers ACT1 and ACT2.

Referring to FIGS. 6 to 9, in one or more aspects, the display panel 110 according to aspects of the present disclosure may further include a side shield SS disposed between the storage capacitor Cst and the first transistor T1.

For example, the side shield SS may be disposed in a line shape. For example, the side shield SS may have a bent line shape. That is, the side shield SS may include a bent portion.

For example, the side shield SS may include a line-shaped contact hole (or a contact hole line) CNT_N1 to which the second capacitor electrode PLT2 and the first gate electrode G1 are connected. For example, the line-shaped contact hole (or the contact hole line) CNT_N1 may be formed in a trench shape.

Referring to FIGS. 6 to 9, in one or more aspects, the display panel 110 according to aspects of the present disclosure may include a lower shield BS located between the substrate SUB and the buffer layer BUF and overlapping with the first active layer ACT1.

For example, the lower shield BS may include one of copper, aluminum, molybdenum (Mo), titanium (Ti), molybdenum-titanium (MoTi), or the like.

Hereinafter, the first transistor T1 and the storage capacitor Cst will be described in more detail with reference to FIGS. 6 to 9.

Referring to FIGS. 6 to 9, the first drain electrode D1 of the first transistor T1 may be connected to the driving voltage line DVL through a contact hole CNT_N3, and the first source electrode S1 of the first transistor T1 may be connected to the first capacitor electrode PLT1 included in the storage capacitor Cst through a contact hole CNT_N2.

Referring to FIGS. 6 to 9, in one or more aspects, in the display panel 110 according to aspects of the present disclosure, the storage capacitor Cst may further include a third capacitor electrode PLT3.

The third capacitor electrode PLT3 may be electrically connected to the first capacitor electrode PLT1 through a contact hole CNT_PLT1, 3.

The first capacitor electrode PLT1 may be electrically connected to the first source electrode S1. Accordingly, the third capacitor electrode PLT3 may be electrically connected to the first source electrode S1.

In other words, the first capacitor electrode PLT1 and the third capacitor electrode PLT3 may be electrically connected to the first source electrode S1 of the first transistor T1.

The second capacitor electrode PLT2 may be electrically connected to the first gate electrode G1 of the first transistor T1.

In one or more aspects, in the display panel 110 according to aspects of the present disclosure, the storage capacitor Cst may include a first storage capacitor Cst1 between the first capacitor electrode PLT1 and the second capacitor electrode PLT2, and a second storage capacitor Cst2 between the second capacitor electrode PLT2 and the third capacitor electrode PLT3.

The first storage capacitor Cst1 and the second storage capacitor Cst2 may be electrically connected in parallel. That is, the storage capacitor Cst may be configured with the first storage capacitor Cst1 and the second storage capacitor Cst2, which are electrically connected in parallel to each other. Thus, such a double capacitor parallel structure of the storage capacitor Cst may lead to an increase in the capacitance of the storage capacitor Cst.

Referring to FIGS. 6 to 9, the second drain electrode D2 of the second transistor T2 may be connected to the data signal line DL, and the second source electrode S2 of the second transistor T2 may be formed by the second capacitor electrode PLT2 included in the storage capacitor Cst or may be connected to the second capacitor electrode PLT2. The second gate electrode G2 of the second transistor T2 may be a portion of the scan signal line SCL.

Referring to FIGS. 6 to 9, the lower shield BS may be electrically connected to the first source electrode S1 of the first transistor T1.

Accordingly, the first source electrode S1 of the first transistor T1 may be electrically connected to the first capacitor electrode PLT1, the third capacitor electrode PLT3, and the lower shield BS.

As shown in FIGS. 7 and 9, the lower shield BS may be formed integrally, as one-piece, with the third capacitor electrode PLT3.

Referring to FIGS. 6 to 9, in one or more aspects, in the display panel 110 according to aspects of the present disclosure, the first gate electrode G1 of the first transistor T1 may include a first lower gate electrode G1a and a first upper gate electrode G1b.

The first upper gate electrode G1b may be disposed on the first lower gate electrode G1a such that the first upper gate electrode G1b and the first lower gate electrode G1a contact with each other.

The gate insulating layer GI may be disposed under the first lower gate electrode G1a. For example, the gate insulating layer GI may be disposed between the first lower gate electrode G1a and the first active layer ACT1. In this example, the gate insulating layer GI may be disposed without being etched (i.e., have an unetched structure or an etchless structure)), and may be disposed such that the gate insulating layer GI covers the first source electrode S1 and the first drain electrode D1.

As the first gate electrode G1 has a double-layered electrode structure including the first lower gate electrode G1a and the first upper gate electrode G1b, the first lower gate electrode G1a may overlap with the first active layer ACT1, overlap with all or at least a portion of the first source electrode S1, and overlap with all or at least a portion of the first drain electrode D1.

As the first gate electrode G1 has a double-layered electrode structure including the first lower gate electrode G1a and the first upper gate electrode G1b, the first lower gate electrode G1a, which is located underneath the first upper gate electrode G1b, may be electrically connected to the second capacitor electrode PLT2.

Referring to FIGS. 6 to 9, the first lower gate electrode G1a, which is located underneath the first upper gate electrode G1b, may contact the second capacitor electrode PLT2 and include a same material as the first capacitor electrode PLT1. That is, the first capacitor electrode PLT1 may be disposed in the same material layer as the first lower gate electrode G1a.

For example, the first capacitor electrode PLT1 and the first lower gate electrode G1a may include a pixel electrode material. The first upper gate electrode G1b may include a gate metal material.

A material included in the first capacitor electrode PLT1, which is the uppermost capacitor electrode among a plurality of capacitor electrodes (e.g., the first to third capacitor electrodes PLT1, PLT2, and PLT3) of the storage capacitor Cst between the first source electrode S1 and the first gate electrode G1, may be included in the first gate electrode G1.

As described above, since the first capacitor electrode PLT1 is disposed in the same material layer as the first lower gate electrode G1a and serves as the first electrode E1 representing a pixel electrode, the first capacitor electrode PLT1 and the first electrode E1 may not be formed separately. Accordingly, the number of electrode layers in the display panel 110 may be reduced.

Referring to FIG. 6, in one or more aspects, in the display panel 110 according to aspects of the present disclosure, the gate insulating layer GI may be disposed between the first and second capacitor electrodes PLT1 and PLT2 of the storage capacitor Cst, and the buffer layer BUF may be disposed between the second and third capacitor electrodes PLT2 and PLT3 of the storage capacitor Cst.

In this manner, as the gate insulating layer GI extends without being etched in areas of the transistors T1 and T2 and is disposed between the first capacitor electrode PLT1 and the second capacitor electrode PLT2, the gate insulating layer GI may be therefore used as an insulating layer (i.e., a dielectric layer) for forming the storage capacitor Cst. Accordingly, a distance between the first capacitor electrode PLT1 and the second capacitor electrode PLT2 may be reduced. Thereby, the capacitance of the storage capacitor Cst may be increased.

Further, as described above, as the storage capacitor Cst is formed in a structure where the first storage capacitor Cst1 and the second storage capacitor Cst2 are disposed in parallel to each other, the capacitance of the storage capacitor Cst may be increased.

Thus, as the display panel 110 according to aspects of the present disclosure has a structure capable of increasing the capacitance of the storage capacitor Cst, advantages of reducing an area of the storage capacitor Cst may be provided when designing the storage capacitor Cst to have a desired capacitance.

Referring to FIGS. 6 to 9, in one or more aspects, in the display panel 110 according to aspects of the present disclosure, the second gate electrode G2 of the second transistor T2 may include a second lower gate electrode G2a and a second upper gate electrode G2b.

The second upper gate electrode G2b may be disposed on the second lower gate electrode G2a such that the second upper gate electrode G1b and the second lower gate electrode G2a contact with each other.

The gate insulating layer GI may be disposed under the second lower gate electrode G2a. For example, the gate insulating layer GI may be disposed between the second lower gate electrode G2a and the second active layer ACT2. In this example, the gate insulating layer GI may be disposed without being etched. In other words, the gate insulating layer GI has an unetched structure or an etchless structure, and may be disposed such that the gate insulating layer GI covers the second source electrode S2 and the second drain electrode D2.

The protective layer PAS may be disposed on the first capacitor electrode PLT1, the first gate electrode G1, and the second gate electrode G2, and the bank BK may be disposed on the protective layer PAS.

An emission layer EL may be disposed on the bank BK, and the second electrode E2 may be disposed on the emission layer EL.

The first capacitor electrode PLT1 may be the first electrode E1.

A portion of the emission layer EL may contact at least a portion of the upper surface of the first capacitor electrode PLT1 serving as the first electrode E1 through holes formed in the bank BK and the protective layer PAS.

Referring to FIG. 6, the light emitting area EA of the subpixel SP may overlap with the storage capacitor Cst. That is, the light emitting area EA of the subpixel SP may be located over the storage capacitor Cst.

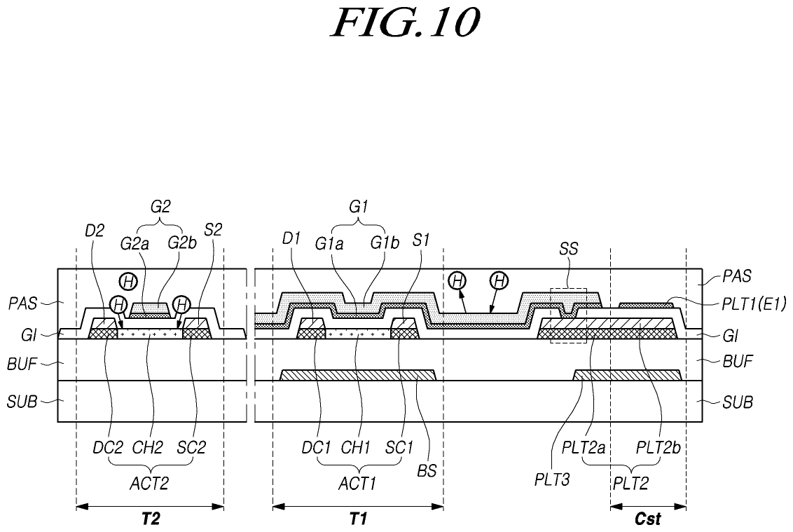

FIG. 10 illustrates example distinct characteristics related to blocking light and hydrogen in the display panel 110 according to aspects of the present disclosure.

Referring to FIG. 10, in one or more aspects, in the display panel 110 according to aspects of the present disclosure, a first transistor T1 and a second transistor T2 (e.g., the first transistor T1 and the second transistor T2 in the figures discussed above) included in each subpixel SP may have different gate electrode structures.

Referring to FIG. 10, a first gate electrode G1 of the first transistor T1, which includes a stack of double layers, may overlap with a first active layer ACT1, and further overlap with a first source electrode S1 and a first drain electrode D1.

Thereby, the first gate electrode G1 may block hydrogen or light from entering the first active layer ACT1 of the first transistor T1 from a protective layer PAS. Accordingly, a phenomenon in which the threshold voltage of the first transistor T1 decreases (i.e., a negative shift in the threshold voltage) may be prevented. As a result, the driving performance of the first transistor T1, which is required to serve as a driving transistor, may be improved.

Referring to FIG. 10, as described above, while the first gate electrode G1 of the first transistor T1 may overlap with the first active layer ACT1, and further overlap with the first source electrode S1 and the first drain electrode D1, a second gate electrode G2 of the second transistor T2 may overlap with a portion of a second active layer ACT2, but not overlap with a second source electrode S2 and a second drain electrode D2.

Thereby, hydrogen or light may enter the second active layer ACT2 of the second transistor T2 from the protective layer PAS. This may cause a phenomenon in which the threshold voltage of the second transistor T2 decreases (i.e., a negative shift in the threshold voltage). As a result, the switching performance and reliability of the second transistor T2, which are required to serve as a switching transistor, may be improved.

Referring to FIG. 10, in one or more aspects, the display panel 110 according to aspects of the present disclosure may include a substrate SUB, and the first transistor T1 and the second transistor T2 over the substrate SUB.

The first transistor T1 may include the first active layer ACT1, the first source electrode S1 connected to one side of the first active layer ACT1, and the first drain electrode D1 connected to another side of the first active layer ACT1, and the first gate electrode G1 overlapping with all or at least a portion of the first active layer ACT1.

The second transistor T2 may include the second active layer ACT2, the second source electrode S2 connected to one side of the second active layer ACT2, and the second drain electrode D2 connected to another side of the second active layer ACT2, and the second gate electrode G2 overlapping with a portion of the second active layer ACT2.

Referring to FIG. 10, the display panel 110 may further include a gate insulating layer GI disposed between the first active layer ACT1 and the first gate electrode G1 and between the second active layer ACT2 and the second gate electrode G2.

Hydrogen or light generated above the first gate electrode G1 may be blocked by the first gate electrode G1 from traveling downward. Therefore, such hydrogen or light cannot be allowed to travel below the first gate electrode G1.

However, in some instances, hydrogen or light generated above the second gate electrode G2 may not be blocked by the second gate electrode G2 from traveling sideways, and then may reach a side edge of the second gate electrode G2. Thereafter, such hydrogen or light may enter the second active layer ACT2 located under the second gate electrode G2.

Accordingly, a concentration of hydrogen or an amount of light being exposed in a portion between the first active layer ACT1 and the first gate electrode G1 among portions of the gate insulating layer GI may be less than a concentration of hydrogen or an amount of light being exposed in a portion between the second active layer ACT2 and the second gate electrode G2 among the portions of the gate insulating layer GI.

Referring to FIGS. 6 to 10, in the first transistor T1, as the first gate electrode G1 overlap withs the first source electrode S1 and also overlap withs the first drain electrode D1, the capacitance of a parasitic capacitor between the first gate electrode G1 and the first source electrode S1 and the capacitance of a parasitic capacitor between the first gate electrode G1 and the first drain electrode D1 may increase. Thereby, the performance of the first transistor T1 may become poor.

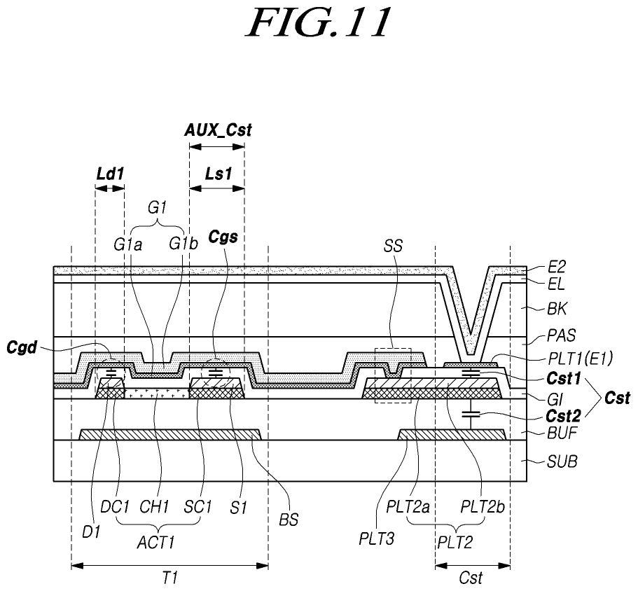

In one or more aspects, the display panel 110 according to aspects of the present disclosure may have a source-drain asymmetric structure capable of preventing the decrease of device performance due to such parasitic capacitors even when the first gate electrode G1 overlap withs the first source electrode S1 and the first drain electrode D1. Hereinafter, in one or more aspects, the source-drain asymmetric structure of the display panel 110 will be described with reference to FIG. 11.

FIG. 11 illustrates an example parasitic capacitor utilization structure in the display panel 110 according to aspects of the present disclosure.

Referring to FIG. 11, in the first transistor T1, since the first gate electrode G1 overlap withs the first source electrode S1 and the first drain electrode D1, a first parasitic capacitor Cgs may be formed between the first gate electrode G1 and the first source electrode S1, and a second parasitic capacitor Cgd may be formed between the first gate electrode G1 and the first drain electrode D1.

Referring to FIG. 11, as the capacitance of a storage capacitor Cst increases, it may be more advantageous for the display panel 110 to perform display driving. For example, such a storage capacitor Cst may be formed between the first gate electrode G1 and the first source electrode S1.

Referring to FIG. 11, since the first parasitic capacitor Cgs and the storage capacitor Cst are formed in the same location, an increase in the capacitance of the first parasitic capacitor Cgs, which is formed between the first gate electrode G1 and the first source electrode S1, may result in an increase in the capacitance of the storage capacitor Cst.

Accordingly, the increase in the capacitance of the first parasitic capacitor Cgs between the first gate electrode G1 and the first source electrode S1 may be advantageous to display driving.

However, since the second parasitic capacitor Cgd is formed between the first gate electrode G1 and the first drain electrode D1, an increase in the capacitance of the second parasitic capacitor Cgd may be disadvantageous to display driving.

Referring to FIG. 11, in one or more aspects, in the display panel 110, the first parasitic capacitor Cgs formed between the first gate electrode G1 and the first source electrode S1 may be an additional storage capacitor AUX_Cst. That is, the overlap with between the first source electrode S1 and the first gate electrode G1 may result in the additional storage capacitor AUX_Cst being formed.

Referring to FIG. 11, in one or more aspects, the display panel 110 according to aspects of the present disclosure may have a structure in which an area of the first source electrode S1 is greater than that of the first drain electrode D1. This structure may be referred to as a source-drain asymmetric structure.

Thus, as the source-drain asymmetric structure is implemented in the display panel 110, the area where the first source electrode S1 and the first gate electrode G1 overlap with each other may be greater than the area where the first drain electrode D1 and the first gate electrode G1 overlap with each other.

Referring to FIG. 11, a length Ls1 of the first source electrode S1 in any one direction (e.g., the horizontal direction) may be greater than a length Ld1 of the first drain electrode D1 in any one direction (e.g., the horizontal direction).

Referring to FIG. 11, as the display panel 110 has the source-drain asymmetric structure, the capacitance of the first parasitic capacitor Cgs, which is formed between the first gate electrode G1 and the first source electrode S1, may be maximally increased, and the capacitance of the second parasitic capacitor Cgd, which is formed between the first gate electrode G1 and the first drain electrode D1, may be maximally reduced.

Referring to FIG. 11, as the display panel 110 has the source-drain asymmetric structure, the capacitance of the additional storage capacitor AUX_Cst as a capacitor corresponding to the first parasitic capacitor Cgs, which is formed between the first gate electrode G1 and the first source electrode S1, may be much greater than the capacitance of the second parasitic capacitor Cgd, which is formed between the first gate electrode G1 and the first drain electrode D1.

Therefore, even when the first gate electrode G1 extends, and overlap withs the first source electrode S1 and the first drain electrode D1, a decrease in device performance due to parasitic capacitors (Cgd and Cgs) may be prevented or reduced because the first transistor T1 has the asymmetric source-drain structure.

Since the first transistor T1 has the asymmetric source-drain structure, the addition of the additional storage capacitor AUX_Cst to the storage capacitor Cst may be advantageous to display driving.

For example, the first transistor T1 may be a top gate transistor in which the first gate electrode is located over the first active layer and/or an oxide semiconductor transistor. The first transistor T1 may have a structure in which the gate insulating layer GI is not etched.

For example, the second transistor T2 may be a top gate transistor in which the second gate electrode is located over the second active layer and/or an oxide semiconductor transistor. The second transistor T2 may have a structure in which the gate insulating layer GI is not etched.

Referring to 6 to 11, in one or more aspects, in the process of manufacturing the display panel 110, when the source electrodes (S1 and S2) and the drain electrodes (D1 and D2) of the first and second transistors (T1 and T2) are formed, the active layers ACT1 and ACT2 may be formed together using a halftone mask without using a separate mask. Accordingly, in one or more aspects, the display panel 110 may be considered to have a structure capable of reducing the number of masks required in the manufacturing process.

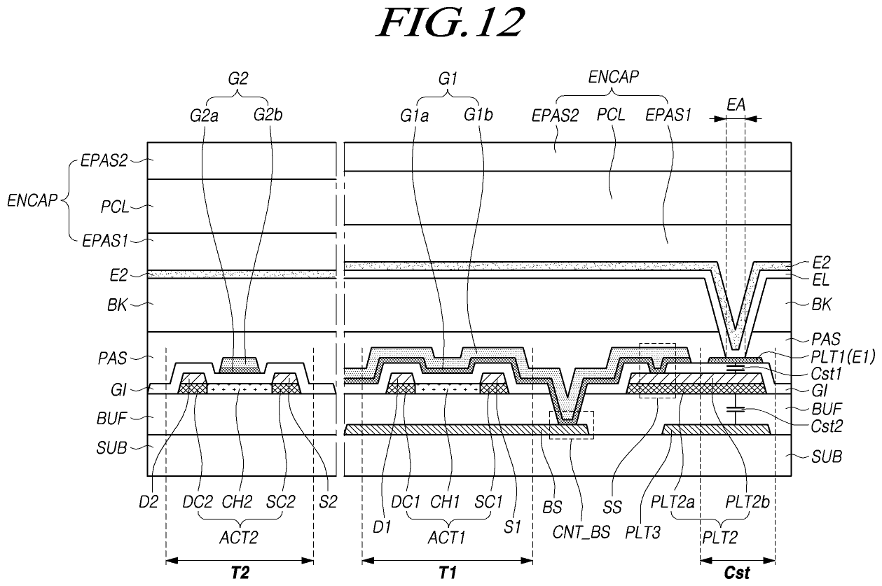

FIG. 12 is an example cross-sectional view of the display panel 110 according to aspects of the present disclosure.

The cross-sectional structure (stack configuration) of FIG. 12 is equal to the cross-sectional structure (stack configuration) of FIG. 6 except for a connection structure of a lower shield BS.

Referring to FIG. 12, in one or more aspects, the lower shield BS may not be electrically connected to the first source electrode S1 of the first transistor T1. The lower shield BS may be electrically connected to the first gate electrode G1 of the first transistor T1 through holes CNT_BS formed in the gate insulating layer GI and the buffer layer BUF.

In these aspects, the first gate electrode G1 may be a top gate electrode of the first transistor T1, and the lower shield BS may be a bottom gate electrode of the first transistor T1.

Thus, in the aspect where the lower shield BS is electrically connected to the first gate electrode G1 of the first transistor T1, the first transistor T1 may have a double gate electrode structure including both the top gate electrode and the bottom gate electrode.

Referring to FIG. 12, the first source electrode S1 of the first transistor T1 may be electrically connected to the first capacitor electrode PLT1 and the third capacitor electrode PLT3.

Referring to FIG. 12, the first gate electrode G1 of the first transistor T1 may be electrically connected to the second capacitor electrode PLT2 and the lower shield BS.

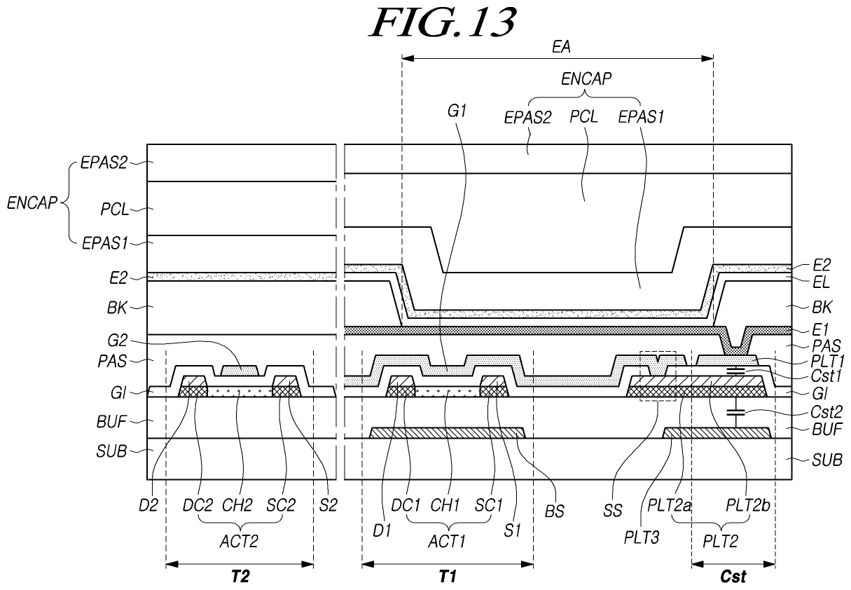

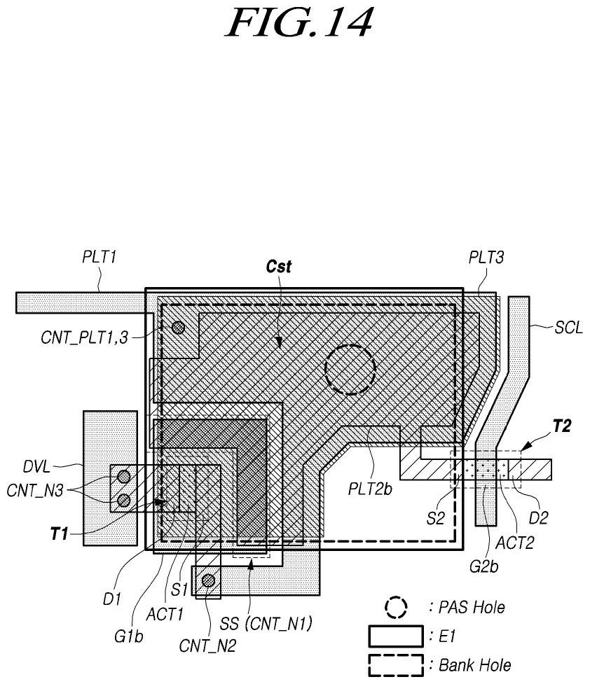

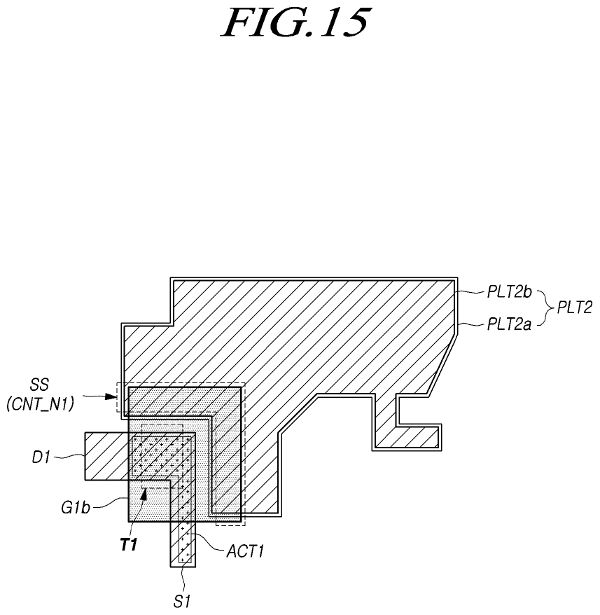

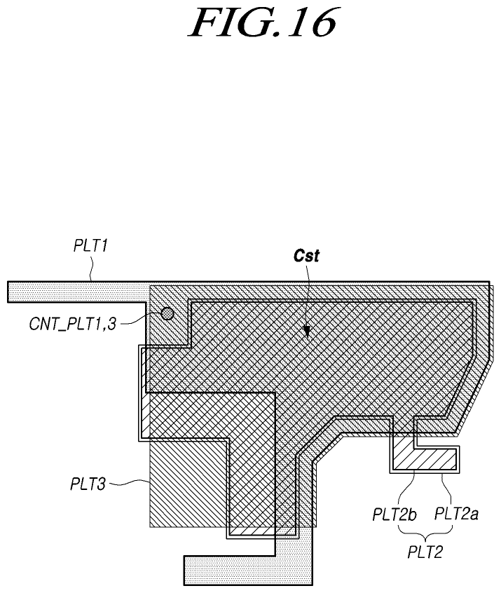

FIG. 13 is an example cross-sectional view of the display panel 110 according to aspects of the present disclosure. FIG. 14 is an example plan view of the display panel 110 of FIG. 13. FIG. 15 is an example plan view illustrating selected portions related to the first transistor T1 in the plan view of FIG. 14. FIG. 16 is an example plan view illustrating selected portions related to a storage capacitor Cst in the plan view of FIG. 14.

In one or more aspects, in the display panel 110 according to aspects of the present disclosure, the feature that the first gate electrode G1 may overlap with the first source electrode S1 and the first drain electrode D1, which is illustrated in FIG. 6, is equally implemented in the configuration of FIG. 13.

However, respective stackup configurations of the display panel 110 illustrated in FIG. 13 and FIG. 6 may be different in stackup configurations (e.g., the number of stacked layers) of the gate electrodes (G1 and G2), a material included in the first capacitor electrode PLT1, and elements included in the light emitting element ED. Hereinafter, in describing these different configurations implemented in the display panel 100 with reference to FIGS. 13 to 16, discussions will be provided by focusing on features different from the configurations of the display panel 100 described above with reference to FIGS. 6 to 9.

Referring to FIG. 13, in one or more aspects, in the display panel 110 according to aspects of the present disclosure, a light emitting element ED, a first transistor T1, a second transistor T2, and a storage capacitor Cst may be disposed in an area where one subpixel SP is formed.

To implement this configuration, in one or more aspects, the display panel 110 may include a substrate SUB and a buffer layer BUF on the substrate SUB.

In one or more aspects, in the display panel 110, the first transistor T1, the second transistor T2, and the storage capacitor Cst may be disposed on the buffer layer BUF.

In one or more aspects, the display panel 110 may include a gate insulating layer GI to form the first transistor T1, the second transistor T2, and the storage capacitor Cst.

In one or more aspects, the display panel 110 may further include a protective layer PAS disposed on the first transistor T1, the second transistor T2, and the storage capacitor Cst. The protective layer PAS may be a layer for protecting the first transistor T1, the second transistor T2, and the storage capacitor Cst.

In one or more aspects, the display panel 110 may further include a bank BK disposed on the protective layer PAS. The bank BK may be a layer for defining a subpixel SP and may be a layer for defining a light emitting area EA of the subpixel SP.

In one or more aspects, the display panel 110 may further include an encapsulation layer ENCAP for preventing penetration of moisture or oxygen into the light emitting element ED.

The encapsulation layer ENCAP may include a first encapsulation layer EPAS1, a second encapsulation layer PCL, and a third encapsulation layer EPAS2. The first encapsulation layer EPAS1 may be located on a second electrode E2 of the light emitting element ED, the second encapsulation layer PCL may be located on the first encapsulation layer EPAS1, and the third encapsulation layer EPAS2 may be located on the second encapsulation layer PCL. The first encapsulation layer EPAS1 and the third encapsulation layer EPAS2 may be, for example, an inorganic material layer, and the second encapsulation layer PCL may be, for example, an organic material layer.

Referring to FIGS. 13 to 16, the first transistor T1 may include a first active layer ACT1, a first source electrode S1, a first drain electrode D1, and a first gate electrode G1.

The first source electrode S1 may be connected to one side of the first active layer ACT1.

The first drain electrode D1 may be connected to another side of the first active layer ACT1.

The first gate electrode G1 may overlap with the first active layer ACT1, overlap with all or at least a portion of the first source electrode S1, and overlap with all or at least a portion of the first drain electrode D1.

The first active layer ACT1 may include a first channel region CH1, a first source connection region SC1 located on one side of the first channel region CH1, and a first drain connection region DC1 located on another side of the first channel region CH1.

The first source electrode S1 may be disposed on the first source connection region SC1 of the first active layer ACT1. The first drain electrode D1 may be disposed on the first drain connection region DC1 of the first active layer ACT1.

Referring to FIGS. 13 to 16, the second transistor T2 may include a second active layer ACT2, a second source electrode S2, a second drain electrode D2, and a second gate electrode G2.

The second source electrode S2 may be connected to one side of the second active layer ACT2.

The second drain electrode D2 may be connected to another side of the second active layer ACT2.

The second gate electrode G2 may overlap with a portion of the second active layer ACT2, and may not overlap with the second source electrode S2 and the second drain electrode D2.

Referring to FIGS. 13 to 16, as described above, the first gate electrode G1 of the first transistor T1 may overlap with the first active layer ACT1, and further overlap with the first source electrode S1 and the first drain electrode D1.

Thereby, the first gate electrode G1 may block hydrogen or light from entering the first active layer ACT1 of the first transistor T1 from the protective layer PAS. Accordingly, a phenomenon in which the threshold voltage of the first transistor T1 decreases (i.e., a negative shift in the threshold voltage) may be prevented. As a result, the driving performance of the first transistor T1, which is required to serve as a driving transistor, may be improved.

Referring to FIGS. 13 to 16, as described above, while the first gate electrode G1 of the first transistor T1 may overlap with the first active layer ACT1, and further overlap with the first source electrode S1 and the first drain electrode D1, the second gate electrode G2 of the second transistor T2 may overlap with a portion of the second active layer ACT2, but not overlap with the second source electrode S2 and the second drain electrode D2.

Thereby, hydrogen or light may enter the second active layer ACT2 of the second transistor T2 from the protective layer PAS. This may cause a phenomenon in which the threshold voltage of the second transistor T2 decreases (i.e., a negative shift in the threshold voltage). As a result, the switching performance and reliability of the second transistor T2, which are required to serve as a switching transistor, may be improved.

Connection relationships between the light emitting element ED, the first transistor T1, the second transistor T2, and the storage capacitor Cst will be briefly described below with reference to FIGS. 13 to 16.

The first gate electrode G1 of the first transistor T1 may be the second source electrode S2 of the second transistor T2 or be electrically connected to the second source electrode S2 of the second transistor T2.

The first source electrode S1 of the first transistor T1 may be the first electrode E1 of the light emitting element ED or be electrically connected to the first electrode E1 of the light emitting element ED.

The first drain electrode D1 of the first transistor T1 may be electrically connected to a driving voltage line DVL (e.g., the driving voltage line DVL in FIG. 5).

The second gate electrode G2 of the second transistor T2 may be a portion of a scan signal line SCL (e.g., the scan signal line SCL shown in FIG. 5) or be electrically connected to the scan signal line SCL.

The second drain electrode D2 of the second transistor T2 may be a portion of a data signal line DL (e.g., the data signal line DL shown in FIG. 5) or be electrically connected to the data signal line DL.

The second source electrode S2 of the second transistor T2 may be the first gate electrode G1 of the first transistor T1 or be electrically connected to the first gate electrode G1.

The storage capacitor Cst may include a first capacitor electrode PLT1 and a second capacitor electrode PLT2.

The first capacitor electrode PLT1 may be the first source electrode S1 of the first transistor T1 or be electrically connected to the first source electrode S1 of the first transistor T1.

In the example where the first capacitor electrode PLT1 is electrically connected to the first source electrode S1 of the first transistor T1, the first capacitor electrode PLT1 may include a same material as the first gate electrode G1. That is, the first capacitor electrode PLT1 may be disposed in the same material layer as the first gate electrode G1.

A material included in the first capacitor electrode PLT1, which is the uppermost capacitor electrode among a plurality of capacitor electrodes (e.g., the first to third capacitor electrodes PLT1, PLT2, and PLT3) of the storage capacitor Cst between the first source electrode S1 and the first gate electrode G1, may be included in the first gate electrode G1.

The second capacitor electrode PLT2 may be the first gate electrode G1 of the first transistor T1 or be electrically connected to the first gate electrode G1 of the first transistor T1.

The second capacitor electrode PLT2 may include a second lower capacitor electrode PLT2a and a second upper capacitor electrode PLT2b.

The second lower capacitor electrode PLT2a may include a same material as the first and second source electrodes S1 and S2 and the first and second drain electrodes D1 and D2. That is, the second lower capacitor electrode PLT2a may be disposed in the same material layer as the first and second source electrodes S1 and S2 and the first and second drain electrodes D1 and D2.

The second upper capacitor electrode PLT2b may include a same semiconductor material as the first and second active layers ACT1 and ACT2. For example, the semiconductor material included in the second upper capacitor electrode PLT2b may be in a conductivity-enabled state or may be in a non-conductivity-enabled state. That is, the second upper capacitor electrode PLT2b may be disposed in the same material layer as the first and second active layers ACT1 and ACT2.

Referring to FIGS. 13 to 16, in one or more aspects, the display panel 110 according to aspects of the present disclosure may include a side shield SS disposed between the storage capacitor Cst and the first transistor T1.

For example, the side shield SS may be disposed in a line shape. For example, the side shield SS may have a bent line shape. That is, the side shield SS may include a bent portion.

For example, the side shield SS may include a line-shaped contact hole (or a contact hole line) CNT_N1 to which the second capacitor electrode PLT2 and the first gate electrode G1 are connected. For example, the line-shaped contact hole (or the contact hole line) CNT_N1 may be formed in a trench shape.

Referring to FIGS. 13 to 16, in one or more aspects, the display panel 110 according to aspects of the present disclosure may include a lower shield BS located between the substrate SUB and the buffer layer BUF and overlapping with the first active layer ACT1.

Hereinafter, the first transistor T1 and the storage capacitor Cst will be described in more detail with reference to FIGS. 13 to 16.

Referring to FIGS. 13 to 16, the first drain electrode D1 of the first transistor T1 may be connected to the driving voltage line DVL through a contact hole CNT_N3, and the first source electrode S1 of the first transistor T1 may be connected to the first capacitor electrode PLT1 included in the storage capacitor Cst through a contact hole CNT_N2.

Referring to FIGS. 13 to 16, in one or more aspects, in the display panel 110 according to aspects of the present disclosure, the storage capacitor Cst may further include a third capacitor electrode PLT3.

The third capacitor electrode PLT3 may be electrically connected to the first capacitor electrode PLT1 through a contact hole CNT_PLT1, 3.

The first capacitor electrode PLT1 may be electrically connected to the first source electrode S1. Accordingly, the third capacitor electrode PLT3 may be electrically connected to the first source electrode S1.

In other words, the first capacitor electrode PLT1 and the third capacitor electrode PLT3 may be electrically connected to the first source electrode S1 of the first transistor T1.

The second capacitor electrode PLT2 may be electrically connected to the first gate electrode G1 of the first transistor T1.

In one or more aspects, in the display panel 110 according to aspects of the present disclosure, the storage capacitor Cst may include a first storage capacitor Cst1 between the first capacitor electrode PLT1 and the second capacitor electrode PLT2, and a second storage capacitor Cst2 between the second capacitor electrode PLT2 and the third capacitor electrode PLT3.

The first storage capacitor Cst1 and the second storage capacitor Cst2 may be electrically connected in parallel. That is, the storage capacitor Cst may be configured with the first storage capacitor Cst1 and the second storage capacitor Cst2, which are electrically connected to each other in parallel. Thus, such a double capacitor parallel structure of the storage capacitor Cst may lead the capacitance of the storage capacitor Cst to increase.

Referring to FIGS. 13 to 16, the second drain electrode D2 of the second transistor T2 may be connected to the data signal line DL, and the second source electrode S2 of the second transistor T2 may be formed by the second capacitor electrode PLT2 included in the storage capacitor Cst or be connected to the second capacitor electrode PLT2. The second gate electrode G2 of the second transistor T2 may be a portion of the scan signal line SCL.

Referring to FIGS. 13 to 16, the lower shield BS may be electrically connected to the first source electrode S1 of the first transistor T1.

Accordingly, the first source electrode S1 of the first transistor T1 may be electrically connected to the first capacitor electrode PLT1, the third capacitor electrode PLT3, and the lower shield B S.

As shown in FIGS. 14 and 15, the lower shield BS may be formed integrally, as one-piece, with the third capacitor electrode PLT3.

Referring to FIG. 13, in one or more aspects, in the display panel 110 according to aspects of the present disclosure, the gate insulating layer GI may be disposed between the first and second capacitor electrodes PLT1 and PLT2 of the storage capacitor Cst, and the buffer layer BUF may be disposed between the second and third capacitor electrodes PLT2 and PLT3 of the storage capacitor Cst.

In this manner, as the gate insulating layer GI extends without being etched in areas of the transistors T1 and T2 and is disposed between the first capacitor electrode PLT1 and the second capacitor electrode PLT2, the gate insulating layer GI may be therefore used as an insulating layer (dielectric layer) for forming the storage capacitor Cst. Accordingly, a distance between the first capacitor electrode PLT1 and the second capacitor electrode PLT2 may be reduced. Thereby, the capacitance of the storage capacitor Cst may be increased.

Further, as described above, as the storage capacitor Cst is formed in a structure where the first storage capacitor Cst1 and the second storage capacitor Cst2 are disposed in parallel to each other, the capacitance of the storage capacitor Cst may be increased.

Thus, as the display panel 110 according to aspects of the present disclosure has a structure capable of increasing the capacitance of the storage capacitor Cst, advantages of reducing an area of the storage capacitor Cst may be provided when designing the storage capacitor Cst to have a desired capacitance.

Referring to FIG. 13, in one or more aspects, in the display panel 110 according to aspects of the present disclosure, the first gate electrode G1 of the first transistor T1 may be formed in a single layer, and the second gate electrode G2 of the second transistor T2 may be formed in a single layer. In another aspect, as illustrated in FIG. 6, in the display panel 110, each of the first gate electrode G1 and the second gate electrode G2 may be formed in a double layer.

Referring to FIGS. 13 to 16, the first gate electrode G1 may include a same material as the first capacitor electrode PLT1.

Referring to FIGS. 13 to 16, the protective layer PAS may be disposed on the first capacitor electrode PLT1, the first gate electrode G1, and the second gate electrode G2, and the bank BK may be disposed on the protective layer PAS.

Referring to FIGS. 13 to 16, in one or more aspects, the first electrode E1 and the first capacitor electrode PLT1 may be separately formed. In another aspect, as illustrated in FIG. 6, in the display panel 110, the first capacitor electrode PLT1 and the first electrode E1 may not be separately formed. For example, the first capacitor electrode PLT1 may serve as the first electrode E1. In this aspect, the first capacitor electrode PLT1 of the display panel 110 in the configuration of FIG. 6 may include a same material as the first lower gate electrode G1a. For example, the first capacitor electrode PLT1 and the first lower gate electrode G1a of the display panel 110 in the configuration of FIG. 6 may include a pixel electrode material.

Referring to FIGS. 13 to 16, the first electrode E1 may be disposed between the protective layer PAS and the bank BK. The first electrode E1 may be connected to the first capacitor electrode PLT1 through a hole formed in the protective layer PAS.

Referring to FIGS. 13 to 16, the emission layer EL may be disposed on the bank BK and may contact an exposed portion of the upper surface of the first electrode E1 through a hole formed in the bank BK. The second electrode E2 may be located on the emission layer EL.

Referring to FIG. 13, a light emitting area EA of a corresponding subpixel SP may overlap with the first transistor T1. That is, the light emitting area EA of the subpixel SP may be located over the first transistor T1.

In this configuration, since the light emitting area EA of the subpixel SP is located over the first transistor T1, the respective light emitting area EA of each subpixel SP of the display panel 110 in the configuration of FIG. 13 may have a size greater than the respective light emitting area EA of each subpixel SP of the display panel 110 in the configuration of FIG. 6.

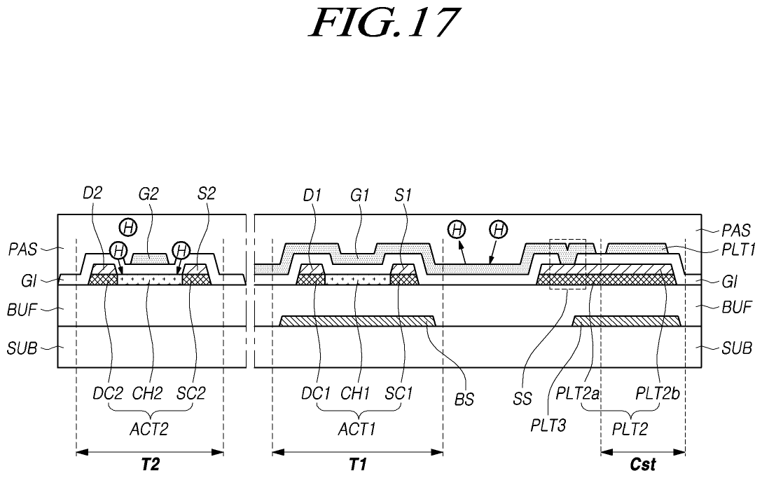

FIG. 17 illustrates example distinct characteristics related to blocking light and hydrogen in the display panel 110 according to aspects of the present disclosure.

Referring to FIG. 17, in one or more aspects, in the display panel 110 according to aspects of the present disclosure, a first transistor T1 and a second transistor T2 (e.g., the first transistor T1 and the second transistor T2 in the figures discussed above) included in each subpixel SP may have different gate electrode structures.

Referring to FIG. 17, a first gate electrode G1 of the first transistor T1, which is formed in a single layer, may overlap with a first active layer ACT1, and further overlap with a first source electrode S1 and a first drain electrode D1.

Thereby, the first gate electrode G1 may block hydrogen or light from entering the first active layer ACT1 of the first transistor T1 from a protective layer PAS. Accordingly, a phenomenon in which the threshold voltage of the first transistor T1 decreases (i.e., a negative shift in the threshold voltage) may be prevented. As a result, the driving performance of the first transistor T1, which is required to serve as a driving transistor, may be improved.

Referring to FIG. 17, as described above, while the first gate electrode G1 of the first transistor T1 may overlap with the first active layer ACT1, and further overlap with the first source electrode S1 and the first drain electrode D1, a second gate electrode G2 of the second transistor T2 may overlap with a portion of a second active layer ACT2, but not overlap with a second source electrode S2 and a second drain electrode D2.

Thereby, hydrogen or light may enter the second active layer ACT2 of the second transistor T2 from the protective layer PAS. This may cause a phenomenon in which the threshold voltage of the second transistor T2 decreases (i.e., a negative shift in the threshold voltage). As a result, the switching performance and reliability of the second transistor T2, which are required to serve as a switching transistor, may be improved.

Referring to FIG. 17, in one or more aspects, the display panel 110 according to aspects of the present disclosure may include a substrate SUB and the first transistor T1 and the second transistor T2 over the substrate SUB.

The first transistor T1 may include the first active layer ACT1, the first source electrode S1 connected to one side of the first active layer ACT1, and the first drain electrode D1 connected to another side of the first active layer ACT1, and the first gate electrode G1 overlapping with all or at least a portion of the first active layer ACT1.

The second transistor T2 may include the second active layer ACT2, the second source electrode S2 connected to one side of the second active layer ACT2, and the second drain electrode D2 connected to another side of the second active layer ACT2, and the second gate electrode G2 overlapping with a portion of the second active layer ACT2.

Referring to FIG. 17, the display panel 110 may further include a gate insulating layer GI disposed between the first active layer ACT1 and the first gate electrode G1 and between the second active layer ACT2 and the second gate electrode G2.

Hydrogen or light generated above the first gate electrode G1 may be blocked by the first gate electrode G1 from traveling downward. Therefore, such hydrogen or light cannot be allowed to travel below the first gate electrode G1.

However, in some instances, hydrogen or light generated above the second gate electrode G2 may not be blocked by the second gate electrode G2 from traveling sideways, and then may reach a side edge of the second gate electrode G2. Thereafter, such hydrogen or light may enter the second active layer ACT2 located under the second gate electrode G2.

Accordingly, a concentration of hydrogen or an amount of light being exposed in a portion between the first active layer ACT1 and the first gate electrode G1 among portions of the gate insulating layer GI, may be less than a concentration of hydrogen or an amount of light being exposed in a portion between the second active layer ACT2 and the second gate electrode G2 among the portions of the gate insulating layer GI.

In some instances, hydrogen or light may be generated during the process of manufacturing the display panel 110 or may be remained or generated inside of the display panel even after the manufacturing of the display panel 110 is completed. For example, hydrogen may be generated in various layers (in particular, various types of insulating layers) located over the first transistor T1, and travel toward the first transistor T1. Light emitted from the light emitting element ED located over the first transistor T1 may travel toward the first transistor T1. In addition, external light may be incident from the first transistor T1 above, and travel toward the first transistor T1.

Referring to FIGS. 13 to 17, in the first transistor T1, as the first gate electrode G1 overlap withs the first source electrode S1 and also overlap withs the first drain electrode D1, the capacitance of a parasitic capacitor between the first gate electrode G1 and the first source electrode S1 and the capacitance of a parasitic capacitor between the first gate electrode G1 and the first drain electrode D1 may increase. Thereby, the performance of the first transistor T1 may become poor.

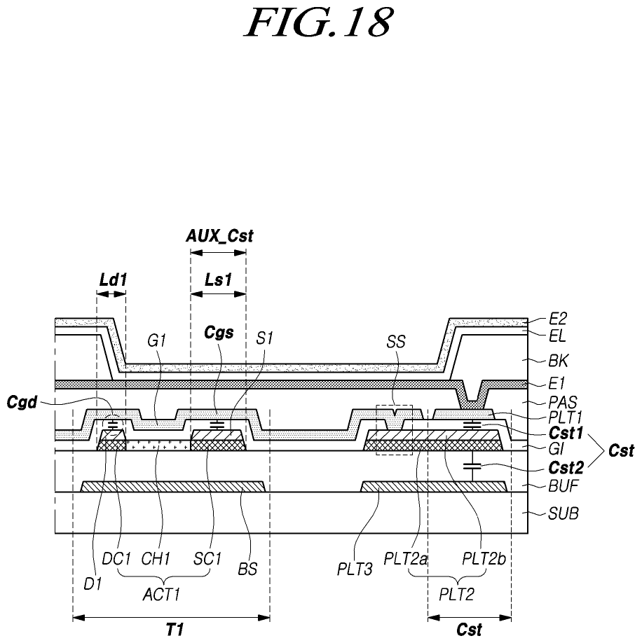

In one or more aspects, the display panel 110 according to aspects of the present disclosure may have a source-drain asymmetric structure capable of preventing the decrease of device performance due to such parasitic capacitors even when the first gate electrode G1, which is formed in a single later, overlap withs the first source electrode S1 and the first drain electrode D1. Hereinafter, in one or more aspects, the source-drain asymmetric structure of the display panel 110 will be described with reference to FIG. 18.

FIG. 18 illustrates an example parasitic capacitor utilization structure in the display panel according to aspects of the present disclosure.

Referring to FIG. 18, in the first transistor T1, since the first gate electrode G1 overlap withs the first source electrode S1 and the first drain electrode D1, a first parasitic capacitor Cgs may be formed between the first gate electrode G1 and the first source electrode S1, and a second parasitic capacitor Cgd may be formed between the first gate electrode G1 and the first drain electrode D1.

Referring to FIG. 18, as the capacitance of a storage capacitor Cst increases, it may be more advantageous for the display panel 110 to perform display driving. For example, such a storage capacitor Cst may be formed between the first gate electrode G1 and the first source electrode S1.

Referring to FIG. 18, since the first parasitic capacitor Cgs and the storage capacitor Cst are formed in the same location, an increase in the capacitance of the first parasitic capacitor Cgs, which is formed between the first gate electrode G1 and the first source electrode S1, may result in an increase in the capacitance of the storage capacitor Cst.

Accordingly, the increase in the capacitance of the first parasitic capacitor Cgs between the first gate electrode G1 and the first source electrode S1 may be advantageous to display driving.

However, since the second parasitic capacitor Cgd is formed between the first gate electrode G1 and the first drain electrode D1, an increase in the capacitance of the second parasitic capacitor Cgd may be disadvantageous to display driving.

Referring to FIG. 18, in one or more aspects, in the display panel 110, the first parasitic capacitor Cgs formed between the first gate electrode G1 and the first source electrode S1 may be an additional storage capacitor AUX_Cst. That is, the overlap with between the first source electrode S1 and the first gate electrode G1 may result in the additional storage capacitor AUX_Cst being formed.

Referring to FIG. 18, in one or more aspects, the display panel 110 according to aspects of the present disclosure may have a structure in which an area of the first source electrode S1 is greater than that of the first drain electrode D1. This structure may be referred to as a source-drain asymmetric structure.

Thus, as the source-drain asymmetric structure is implemented in the display panel 110, the area where the first source electrode S1 and the first gate electrode G1 overlap with each other may be greater than the area where the first drain electrode D1 and the first gate electrode G1 overlap with each other.

Referring to FIG. 18, a length Ls1 of the first source electrode S1 in any one direction (e.g., the horizontal direction) may be greater than a length Ld1 of the first drain electrode D1 in any one direction (e.g., the horizontal direction).

Referring to FIG. 18, as the display panel 110 has the source-drain asymmetric structure, the capacitance of the first parasitic capacitor Cgs, which is formed between the first gate electrode G1 and the first source electrode S1, may be maximally increased, and the capacitance of the second parasitic capacitor Cgd, which is formed between the first gate electrode G1 and the first drain electrode D1, may be maximally reduced.

Referring to FIG. 18, as the display panel 110 has the source-drain asymmetric structure, the capacitance of the additional storage capacitor AUX_Cst as a capacitor corresponding to the first parasitic capacitor Cgs, which is formed between the first gate electrode G1 and the first source electrode S1, may be much greater than the capacitance of the second parasitic capacitor Cgd, which is formed between the first gate electrode G1 and the first drain electrode D1.

Therefore, even when the first gate electrode G1 extends, and overlap withs the first source electrode S1 and the first drain electrode D1, a decrease in device performance due to parasitic capacitors (Cgd and Cgs) may be prevented or reduced because the first transistor T1 has the asymmetric source-drain structure.

Since the first transistor T1 has the asymmetric source-drain structure, the addition of the additional storage capacitor AUX_Cst to the storage capacitor Cst may be advantageous to display driving.

For example, the first transistor T1 may be a top gate transistor and/or an oxide semiconductor transistor. The first transistor T1 may have a structure in which the gate insulating layer GI is not etched.

For example, the second transistor T2 may be a top gate transistor and/or an oxide semiconductor transistor. The second transistor T2 may have a structure in which the gate insulating layer GI is not etched.

Referring to 13 to 18, in one or more aspects, in the process of manufacturing the display panel 110, when the source electrodes (S1 and S2) and the drain electrodes (D1 and D2) of the first and second transistors (T1 and T2) are formed, the active layers ACT1 and ACT2 may be formed together using a halftone mask without using a separate mask. Accordingly, in one or more aspects, the display panel 110 may be considered to have a structure capable of reducing the number of masks required in the manufacturing process.

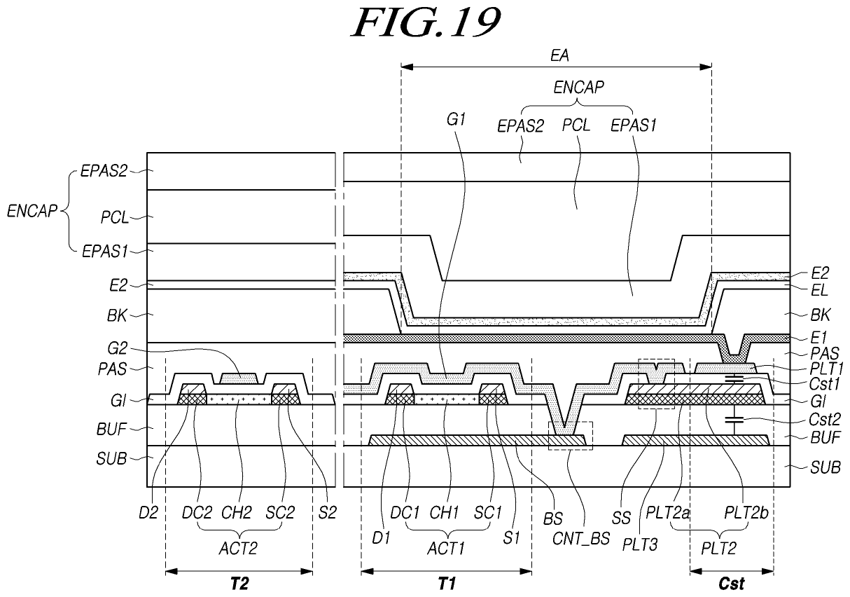

FIG. 19 is an example cross-sectional view of the display panel 110 according to aspects of the present disclosure.

The cross-sectional structure (stack configuration) of FIG. 19 is equal to the cross-sectional structure (stack configuration) of FIG. 13 except for a connection structure of a lower shield BS.

Referring to FIG. 19, in one or more aspects, the lower shield BS may not be electrically connected to the first source electrode S1 of the first transistor T1. The lower shield BS may be electrically connected to the first gate electrode G1 of the first transistor T1 through holes CNT_BS formed in the gate insulating layer GI and the buffer layer BUF.

In these aspects, the first gate electrode G1 may be a top gate electrode of the first transistor T1, and the lower shield BS may be a bottom gate electrode of the first transistor T1.

Thus, in the aspect where the lower shield BS is electrically connected to the first gate electrode G1 of the first transistor T1, the first transistor T1 may have a double gate electrode structure including both the top gate electrode and the bottom gate electrode.

Referring to FIG. 19, the first source electrode S1 of the first transistor T1 may be electrically connected to the first capacitor electrode PLT1 and the third capacitor electrode PLT3, and the first gate electrode G1 of the first transistor T1 may be electrically connected to the lower shield BS.

The aspects of the touch display device 100 according to aspects of the present disclosure described above may be briefly discussed as follows.

According to aspects of the present disclosure, a display panel may be provided that includes a data signal line for supplying a data signal, a scan signal line for supplying a scan signal, and a subpixel connected to the data signal line and the scan signal line and including a first transistor.

The first transistor may include a first active layer, a first source electrode connected to one side of the first active layer, a first drain electrode connected to another side of the first active layer, and a first gate electrode overlapping with the first active layer, overlapping with all or at least a portion of the first source electrode, and overlapping with all or at least a portion of the first drain electrode.

The subpixel may further include a light emitting element, a second transistor, and a storage capacitor.

The light emitting element may include a first electrode, an emission layer, and a second electrode.

The second transistor may include a second active layer, a second source electrode connected to one side of the second active layer, a second drain electrode connected to another side of the second active layer, and a second gate electrode overlapping with a portion of the second active layer, but not overlapping with the second source electrode and the second drain electrode.

The first transistor may be a driving transistor, and the second transistor may be a scan transistor, which is a type of switching transistor.

The first gate electrode may be the second source electrode or be electrically connected to the second source electrode, and the first source electrode may be the first electrode or be electrically connected to the first electrode.

The second gate electrode may be a portion of the scan signal line or be electrically connected to the scan signal line. The second drain electrode may be a portion of the data signal line or be electrically connected to the data signal line. The second source electrode may be the first gate electrode or be electrically connected to the first gate electrode.

The storage capacitor may include a first capacitor electrode and a second capacitor electrode. The first capacitor electrode may be the first source electrode or be electrically connected to the first source electrode. The second capacitor electrode may be the first gate electrode or be electrically connected to the first gate electrode.

In one or more aspects, the display panel may further include a side shield disposed between the storage capacitor and the first transistor. The side shield may include a trench-shaped contact hole (or a trench-shaped contact hole line) to which the second capacitor electrode and the first gate electrode are connected.

The side shield may include a bent portion.

In one or more aspects, the display panel may further include a substrate, a buffer layer on the substrate, and a lower shield located between the substrate and the buffer layer and overlapping with the first active layer.

The storage capacitor may further include a third capacitor electrode electrically connected to the first source electrode and the first capacitor electrode.

The storage capacitor may include a first storage capacitor between the first capacitor electrode and the second capacitor electrode, and a second storage capacitor between the second capacitor electrode and the third capacitor electrode. The first storage capacitor and the second storage capacitor may be electrically connected in parallel.

For example, the lower shield may be electrically connected to the first source electrode.

In another example, the lower shield may be electrically connected to the first gate electrode.

The first gate electrode may include a first lower gate electrode and a first upper gate electrode. The first lower gate electrode may contact the second capacitor electrode and include a same material as the first capacitor electrode.

In one or more aspects, the display panel may include a protective layer disposed on the first capacitor electrode, the first gate electrode, and the second gate electrode, and a bank disposed on the protective layer.

The emission layer may be disposed on the bank, and the second electrode may be disposed on the emission layer.

The first capacitor electrode may be the first electrode.

A portion of the emission layer may contact a portion of the upper surface of the first capacitor electrode serving as the first electrode through holes formed in the bank and the protective layer.

In one or more aspects, a light emitting area of the subpixel disposed in the display panel may be located over the storage capacitor.

In one or more aspects, the first gate electrode disposed in the display panel may be formed in a single layer and include a same material as the first capacitor electrode.

In one or more aspects, the display panel may include the protective layer disposed on the first capacitor electrode, the first gate electrode, and the second gate electrode, and the bank disposed on the protective layer.

The first electrode may be disposed between the protective layer and the bank, and the first electrode may be connected to the first capacitor electrode through a hole formed in the protective layer.

The emission layer may be disposed on the bank and may contact an exposed portion of the upper surface of the first electrode through a hole formed in the bank.

In one or more aspects, the light emitting area of the subpixel disposed in the display panel may overlap with the first transistor and be located over the first transistor.

In one or more aspects, in the display panel, an area in which the first source electrode overlap withs the first gate electrode may be greater than an area in which the first drain electrode overlap withs the first gate electrode.

In one or more aspects, in the display panel, an additional storage capacitor may be formed by the overlap with between the first source electrode and the first gate electrode.

According to aspects of the present disclosure, a display device may be provided that includes a substrate, first and second transistors on the substrate.

The first transistor may include a first active layer, a first source electrode connected to one side of the first active layer, a first drain electrode connected to another side of the first active layer, and a first gate electrode overlapping with all or at least a portion of the first active layer.

The second transistor may include a second active layer, a second source electrode connected to one side of the second active layer, a second drain electrode connected to another side of the second active layer, and a second gate electrode overlapping with a portion of the second active layer.

The first gate electrode of the first transistor may be a top-gate electrode located over the first active layer, and the second gate electrode of the second transistor may be a top-gate electrode located over the second active layer.

The display device may further include a gate insulating layer disposed between the first active layer and the first gate electrode and between the second active layer and the second gate electrode.

For example, a concentration of hydrogen or an amount of light being exposed in a portion between the first active layer and the first gate electrode among portions of the gate insulating layer may be less than a concentration of hydrogen or an amount of light being exposed in a portion between the second active layer and the second gate electrode among the portions of the gate insulating layer.

A concentration of hydrogen or an amount of light being exposed in the first active layer may be less than a concentration of hydrogen or an amount of light being exposed in the second active layer.

The first gate electrode may overlap with all or at least a portion of the first source electrode, and overlap with all or at least a portion of the first drain electrode. In contrast, the second gate electrode may not overlap with the second source electrode and the second drain electrode.

The display panel may include a storage capacitor including a first capacitor electrode and a second capacitor electrode.

The first gate electrode may include a material included in the first capacitor electrode. The first capacitor electrode may be electrically connected to the first source electrode, and the second capacitor electrode may be electrically connected to the first gate electrode.

The storage capacitor may further include a third capacitor electrode, and the third capacitor electrode may be electrically connected to the first source electrode.

A material included in the uppermost capacitor electrode (e.g., the first capacitor electrode) among a plurality of capacitor electrodes (e.g., the first to third capacitor electrodes PLT1, PLT2, and PLT3) of the storage capacitor between the first source electrode and the first gate electrode may be included in the first gate electrode.

According to the aspects described herein, a display panel and a display device may be provided that include a first transistor having a structure capable of providing desired performance even when being exposed to light, hydrogen, or the like. The first transistor may be, for example, a driving element (i.e., driving transistor).

According to the aspects described herein, a display panel and a display device may be provided that include a first transistor having a structure capable of preventing or reducing the exposure of the first transistor to light, hydrogen, or the like even when the first transistor has a top-gate structure that is more likely to be exposed to light, hydrogen, or the like.

According to the aspects described herein, a display panel and a display device may be provided that include a first transistor having a structure capable of preventing or reducing the exposure of the first transistor to light, hydrogen, or the like even when the display device has a top-emission structure that is more likely to be exposed to light, hydrogen, or the like.

According to the aspects described herein, a display panel and a display device may be provided that include different types of transistors each designed to have a respective optimized structure according to being advantageous or disadvantageous to a variance in characteristics of the transistors when being exposed to light, hydrogen, or the like.

In these aspects, the different types of transistors may include a first transistor serving as a driving transistor (i.e., a driving element) and a second transistor serving as a switching transistor (i.e., a switching element, for example, a scan transistor, a sensing transistor, or the like).

When the driving transistor (driving element) is exposed to light, hydrogen, or the like, driving performance thereof may be decreased, and when the switching transistor (switching element) is exposed to light, hydrogen, or the like, switching performance thereof may be improved.

Taking account of these characteristics, the first transistor serving as a driving transistor may be configured to have a gate electrode structure capable of preventing the exposure of the first transistor to light, hydrogen, or the like, and the second transistor serving as a switching transistor may be configured to have a gate electrode structure capable of allowing the second transistor to be exposed to light, hydrogen, or the like.

The aspects of the present disclosure described above have been described for illustrative purposes; those skilled in the art will appreciate that various modifications, additions and substitutions are possible, without departing from the scope and spirit of the disclosure as disclosed in the accompanying claims.

Although the exemplary aspects have been described for illustrative purposes, a person skilled in the art will appreciate that various modifications and applications are possible without departing from the essential characteristics of the present disclosure. For example, the specific components of the exemplary aspects may be variously modified.

The above description and the accompanying drawings provide an example of the technical idea of the present disclosure for illustrative purposes only. That is, the disclosed aspects are intended to illustrate the scope of the technical idea of the present disclosure. Thus, the scope of the present disclosure is not limited to the aspects shown, but is to be accorded the widest scope consistent with the claims.

The scope of protection of the present disclosure is to be construed according to the claims, and all technical ideas within the scope of the claims should be interpreted as being included in the scope of the present disclosure. The various aspects described above may be combined to provide further aspects. These and other changes may be made to the aspects in light of the above-detailed description. In general, in the following claims, the terms used should not be construed to limit the claims to the specific aspects disclosed in the specification and the claims, but should be construed to include all possible aspects along with the full scope of equivalents to which such claims are entitled. Accordingly, the claims are not limited by the specific aspects.

What is claimed is:

1. A display panel comprising:
a data signal line supplying a data signal;
a scan signal line supplying a scan signal; and
a first transistor disposed in a subpixel where the data signal line and the scan signal line are connected, the first transistor comprising,
a first active layer, a first source electrode connected to one side of the first active layer,
a first drain electrode connected to another side of the first active layer, and
a first gate electrode overlapping with the first active layer, overlapping with at least a portion of the first source electrode, and overlapping with at least a portion of the first drain electrode.

2. The display panel of claim 1, further comprising a light emitting element, a second transistor, and a storage capacitor disposed in the subpixel,
wherein the light emitting element comprises a first electrode, an emission layer, and a second electrode, and
wherein the second transistor comprises:
a second active layer;
a second source electrode connected to one side of the second active layer;
a second drain electrode connected to another side of the second active layer; and
a second gate electrode overlapping with a portion of the second active layer, and not overlapping with the second source electrode and the second drain electrode.

3. The display panel of claim 2, wherein the first gate electrode is a top-gate electrode located over the first active layer, and the second gate electrode is a top-gate electrode located over the second active layer,
wherein the first gate electrode is the second source electrode or is electrically connected to the second source electrode, and the first source electrode is the first electrode or is electrically connected to the first electrode, and
wherein the second gate electrode is a portion of the scan signal line or is electrically connected to the scan signal line;
wherein the second drain electrode is a portion of the data signal line or is electrically connected to the data signal line; and
wherein the second source electrode is the first gate electrode or is electrically connected to the first gate electrode.

4. The display panel of claim 2, wherein the storage capacitor comprises a first capacitor electrode and a second capacitor electrode, and
wherein the first capacitor electrode is the first source electrode or is electrically connected to the first source electrode, and the second capacitor electrode is the first gate electrode or is electrically connected to the first gate electrode.

5. The display panel of claim 4, further comprising a side shield disposed between the storage capacitor and the first transistor,
wherein the side shield comprises a trench-shaped contact hole line to which the second capacitor electrode and the first gate electrode are connected, and
wherein the side shield has a bent portion.

6. The display panel of claim 4, further comprising:
a substrate;
a buffer layer on the substrate; and
a lower shield located between the substrate and the buffer layer and overlapping with the first active layer.

7. The display panel of claim 6, wherein the storage capacitor further comprises a third capacitor electrode electrically connected to the first source electrode and the first capacitor electrode,
wherein the storage capacitor comprises a first storage capacitor between the first capacitor electrode and the second capacitor electrode, and a second storage capacitor between the second capacitor electrode and the third capacitor electrode, and
wherein the first storage capacitor and the second storage capacitor are electrically connected in parallel.

8. The display panel of claim 6, wherein the lower shield is electrically connected to the first source electrode.

9. The display panel of claim 8, wherein the lower shield is formed integrally with a capacitor electrode included in the storage capacitor.

10. The display panel of claim 6, wherein the lower shield is electrically connected to the first gate electrode.

11. The display panel of claim 4, wherein the first gate electrode comprises a first lower gate electrode and a first upper gate electrode, and
wherein the first lower gate electrode and the second capacitor electrode contact with each other and the first lower gate electrode includes a same material as the first capacitor electrode.

12. The display panel of claim 11, further comprising:
a protective layer disposed on the first capacitor electrode, the first gate electrode, and the second gate electrode; and
a bank disposed on the protective layer,
wherein the emission layer is disposed on the bank, and the second electrode is disposed on the emission layer, and
wherein the first capacitor electrode is the first electrode, and a portion of the emission layer contacts a portion of an upper surface of the first capacitor electrode serving as the first electrode through holes formed in the bank and the protective layer.

13. The display panel of claim 4, wherein the subpixel has a light emitting area located over the storage capacitor.

14. The display panel of claim 4, wherein the first gate electrode is formed in a single layer and comprises a same material as the first capacitor electrode.

15. The display panel of claim 4, further comprising:
a protective layer disposed on the first capacitor electrode, the first gate electrode, and the second gate electrode; and
a bank disposed on the protective layer,
wherein the first electrode is disposed between the protective layer and the bank, and the first electrode is connected to the first capacitor electrode through a hole formed in the protective layer, and
wherein the emission layer is disposed on the bank and contacts an exposed portion of an upper surface of the first electrode through a hole formed in the bank.

16. The display panel of claim 4, wherein the subpixel has a light emitting area located over the first transistor.

17. The display panel of claim 1, wherein an overlapping area between the first source electrode and the first gate electrode is greater than an overlapping area between the first drain electrode and the first gate electrode.

18. The display panel of claim 2, further comprising an additional storage capacitor formed by overlapping between the first source electrode and the first gate electrode.

19. A display device comprising:
a substrate; and
first and second transistors on the substrate,
wherein the first transistor comprises a first active layer, a first source electrode connected to one side of the first active layer, a first drain electrode connected to another side of the first active layer, and a first gate electrode overlapping with at least a portion of the first active layer,
wherein the second transistor comprises a second active layer, a second source electrode connected to one side of the second active layer, a second drain electrode connected to another side of the second active layer, and a second gate electrode overlapping with a portion of the second active layer,
wherein the display device further comprises a gate insulating layer disposed between the first active layer and the first gate electrode and between the second active layer and the second gate electrode, and
wherein a concentration of hydrogen or an amount of light being exposed in a portion between the first active layer and the first gate electrode among portions of the gate insulating layer is less than a concentration of hydrogen or an amount of light being exposed in a portion between the second active layer and the second gate electrode among the portions of the gate insulating layer.

20. The display device of claim 19, wherein the first gate electrode overlaps with all or at least a portion of the first source electrode, and overlaps with at least a portion of the first drain electrode, and the second gate electrode does not overlap with the second source electrode and the second drain electrode.

21. The display device of claim 20, further comprising a storage capacitor disposed between the first source electrode and the first gate electrode,
wherein an uppermost capacitor electrode in the storage capacitor includes a same material as the first gate electrode.

22. A display device comprising:
a first transistor including a first active layer, a first source electrode connected to one side of the first active layer, a first drain electrode connected to another side of the first active layer, and a first gate electrode overlapping with at least a portion of the first active layer;
a second transistor including a second active layer, a second source electrode connected to one side of the second active layer, a second drain electrode connected to another side of the second active layer, and a second gate electrode overlapping with a portion of the second active layer; and
a storage capacitor disposed between the first source electrode and the first gate electrode,
wherein the first gate electrode has a size greater than that of the second gate electrode, and the first gate electrode is long and wide enough to prevent hydrogen or light penetration into the first active layer.

23. The display device of claim 22, wherein the second gate electrode allows hydrogen or light penetration into the second active layer.

24. The display device of claim 22, further comprising a side shield disposed between the storage capacitor and the first transistor and has a trench-shaped contact hole line to which the second capacitor electrode and the first gate electrode are connected,
wherein the side shield has a bent portion.

25. The display device of claim 22, further comprising a lower shield disposed to overlap with the first active layer.

26. The display device of claim 22, further comprising a protective layer disposed on the first gate electrode and the second gate electrode.
